(19) United States
(12) Patent Application Publication
(10) Pub. No.: US 2026/0040527 A1
(43) Pub. Date: Feb. 5, 2026

(54) HYDROGEN-BLOCKING COLUMNS IN A MEMORY ARRAY

(71) Applicant: Taiwan Semiconductor Manufacturing Company, Ltd., Hsinchu (TW)

(72) Inventors: Yu-Chien CHIU, Hsinchu County (TW); Chien-Hao HUANG, Hsinchu City (TW); Ya-Yun CHENG, Taichung City (TW); Wen-Ling LU, Taoyuan County (TW); Chung-Wei WU, Ju-Bei City (TW); Zhiqiang WU, Hsinchu County (TW)

(21) Appl. No.: 18/788,502

(22) Filed: Jul. 30, 2024

(51) Int. Cl. H10B 12/00

(52) U.S. Cl. CPC H10B 12/33; H10B 12/05

(57) ABSTRACT

Hydrogen-blocking columns may be included between a gate electrode of a transistor structure and one or more other layers of a semiconductor device to prevent, minimize, and/or otherwise reduce hydrogen diffusion into a channel layer of the transistor structure. The hydrogen-blocking columns include one or more materials that resist absorption of hydrogen, which prevents, minimizes, and/or otherwise reduces the likelihood of the hydrogen diffusing into the vertical channel layer of the transistor structure. In this way, the hydrogen-blocking columns prevent, minimize, and/or otherwise reduce the likelihood of hydrogen contamination in the channel layer, which may enable a low current leakage to be achieved for the transistor structure.

### BACKGROUND

A non-volatile memory cell is a type of memory cell that may include a transistor connected in series with a memory element such as a capacitor, a phase change material layer, a resistive layer, and/or a magnetic layer, among other examples. This may be referred to as a one transistor-one memory element (1T-1X) cell. The memory element in a 1T-1X cell selectively stores data (e.g., a logical “1” value or a logical “0” value) based on an electric charge, a resistivity, a capacitance, and/or a magnetic field, among other examples. The state of the memory element may be selectively modified and/or read by using the transistor to charge or discharge the memory element.

### BRIEF DESCRIPTION OF THE DRAWINGS

Aspects of the present disclosure are best understood from the following detailed description when read with the accompanying figures. In accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A and 2B are diagrams of an example implementation of a memory cell structure described herein.

FIGS. 3A and 3B are diagrams of an example implementation of a memory cell structure described herein.

FIGS. 4A-4P are diagrams of an example implementation of forming a memory array of a semiconductor device described herein.

FIGS. 5A-5K are diagrams of an example implementation of forming hydrogen-blocking columns in a memory array of a semiconductor device described herein.

FIG. 6 is a diagram of an example 600 of temperature bias instability for various memory cell structures.

FIG. 7 is a flowchart of an example process associated with forming a memory cell structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a transistor of a 1T-1X memory cell structure may include an oxide-semiconductor channel (e.g., a channel layer that includes an oxide-semiconductor material). The use of an oxide-semiconductor channel may provide reduced current leakage in the 1T-1X memory cell structure relative to an elemental semiconductor channel or a III-V compound semiconductor channel, which may improve charge retention (and thus data retention) in the memory element of the 1T-1X memory cell structure.

However, oxide-semiconductor materials are highly susceptible to hydrogen contamination. If hydrogen diffuses into the oxide-semiconductor channel of the 1T-1X memory cell structure, charge carrier concentration can increase in the oxide-semiconductor channel. The increased charge carrier concentration can cause increased off-current leakage for the 1T-1X memory cell structure, increased positive bias temperature instability (PBTI), and/or increased negative bias temperature instability (NBTI). The increased off-current leakage may increase the rate of charge depletion in the memory element, resulting in an increased refresh rate for replenishing the charge in the memory element in order to prevent data loss. This increases the power consumption of the 1T-1X memory cell structure, which decreases the power efficiency of the 1T-1X memory cell structure. Additionally and/or alternatively, hydrogen contamination in the oxide-semiconductor channel can increase the charge carrier concentration to a point where the 1T-1X memory cell structure becomes stuck in a normally-on configuration, thereby rendering the 1T-1X memory cell structure non-operational. Increasing a gate length of the transistor may decrease the current leakage through the transistor at the expense of reduced memory cell density in a semiconductor device in which the 1T-1X memory cell structure is included.

In some implementations described herein, a semiconductor device includes a memory cell structure (e.g., a 1T-1X memory cell structure) that includes a transistor structure and a storage structure corresponding to the memory element of the memory cell structure. The channel layer of the transistor structure extends in a vertical direction in the semiconductor device (e.g., a z-direction that is approximately perpendicular to a surface of a substrate of the semiconductor device), and the gate electrode and corresponding gate dielectric layer each wrap around the channel layer, which enables the gate length to be increased with minimal to no increase in horizontal or lateral (e.g., x-y direction) size of the memory cell structure. The vertical arrangement of the channel layer increases the channel area of the transistor structure, which enables a low current leakage to be achieved for the memory cell structure, and enables a high horizontal or lateral density of memory cell structures to be achieved in the semiconductor device. The low current leakage of the memory cell structure enables data stored in the storage structure of the memory cell structure to retain data for longer time durations between refreshes, which reduces the power consumption of the memory cell structure and increases the power efficiency of the memory cell structure.

Hydrogen-blocking columns may be included between the gate electrode and one or more other layers of the semiconductor device to prevent, minimize, and/or otherwise reduce hydrogen diffusion into the vertical channel layer of the transistor structure. The hydrogen-blocking columns include one or more materials that resist absorption of hydrogen, which prevents, minimizes, and/or otherwise reduces the likelihood of the hydrogen diffusing into the vertical channel layer of the transistor structure. In this way, the hydrogen-blocking columns prevent, minimize, and/or otherwise reduce the likelihood of hydrogen contamination in the oxide-semiconductor material of the vertical channel layer, which may enable a low current leakage to be achieved for the memory cell structure, and may reduce the likelihood of data corruption and/or failure of the memory cell structure, among other examples.

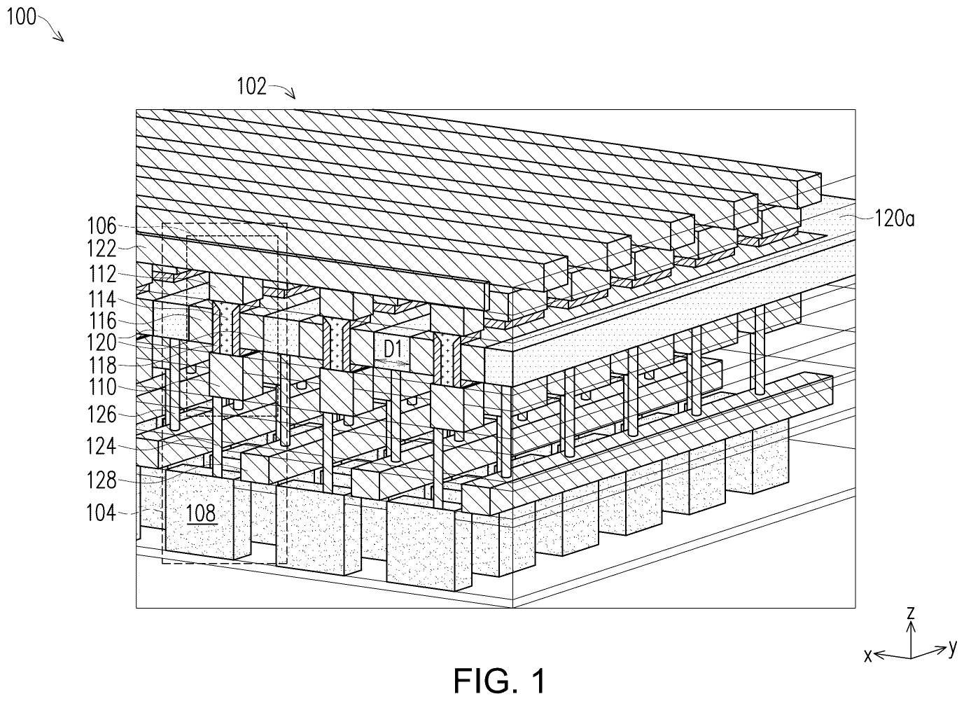

FIG. 1 is a diagram of an example semiconductor device 100 described herein. The semiconductor device 100 may include a semiconductor memory device or another type of semiconductor device that includes a memory array 102 that includes a plurality of memory cell structures 104. In some implementations, the memory array 102 is included in a backend region (e.g., a back end of line (BEOL) region) of the semiconductor device 100. In some implementations, the memory array 102 is included in another region of the semiconductor device 100.

In some implementations, the memory cell structures 104 are arranged in a grid in memory array 102. For example, the memory array 102 may include a plurality of rows and a plurality of columns, where each memory cell structure 104 is located at an intersection between a row and a column in the memory array 102. The rows may extend in an x-direction in the semiconductor device 100, and the columns may extend in a y-direction in the semiconductor device 100. In some implementations, the memory cell structures 104 are configured in another arrangement in the memory array.

A memory cell structure 104 may be a 1T-1X memory cell that includes a transistor structure 106 that is electrically coupled to a storage structure 108. As indicated above, the memory array 102 may be included in a backend region of the semiconductor device 100. Thus, the transistor structures 106 of the memory cell structures 104 may be referred to as backend transistor structures, and the memory cell structures 104 may be referred to as backend memory cell structures.

The transistor structure 106 of a memory cell structure 104 may be located vertically above the storage structure 108 of the memory cell structure 104 in a z-direction in the semiconductor device 100. Alternatively, the storage structure 108 may be located above the transistor structure 106. The transistor structure 106 may be configured to selectively activate and provide access to the associated storage structure 108 so that one or more types of memory operations may be performed for the memory cell structure 104. Examples of such memory operations include a write operation (or program operation) (e.g., in which the storage structure 108 is programmed to store a particular logical value), a read operation (e.g., in which the logical value is read from the storage structure 108), and/or an erase operation (e.g., in which the logical value is erased from the storage structure 108).

The storage structure 108 includes a capacitor structure (e.g., a deep trench capacitor (DTC) structure, a thin film capacitor structure), a ferroelectric storage structure, a magnetic storage structure, a resistive storage structure, a phase change material storage structure, and/or another type of storage structure that is capable of being configured in two or more states corresponding to or more logical values. For example, a first state (e.g., a first charge magnitude, a first polarity, a first resistance) may correspond to a “0” logical value, and a second state (e.g., a second charge magnitude, a second polarity, a second resistance) may correspond to a “1” logical value. In some implementations, a storage structure 108 may be configured with greater than two candidate states.

The storage structure 108 is included vertically below (e.g., in the z-direction) the transistor structure 106 and is electrically coupled to a source/drain electrode 110 (e.g., a bottom source/drain electrode) of the transistor structure 106. A “source/drain electrode” may refer to a source electrode or a drain electrode, individually or collectively, depending upon the context. In some implementations, a source/drain electrode may be both a source electrode for a first transistor structure and a drain electrode for a second transistor structure such that source electrode of the first transistor structure and the drain electrode of the second transistor structure are connected and implemented by the same physical structure. The transistor structure 106 further includes another source/drain electrode 112 (e.g., a top source/drain electrode) above the source/drain electrode 110 in the z-direction.

A channel layer 114 of the transistor structure 106 may be located vertically between (and may extend vertically between) the source/drain electrode 110 and the source/drain electrode 112. Thus, the source/drain electrode 110, the channel layer 114 (a vertical channel layer), and the source/drain electrode 112 are vertically arranged in the z-direction in the transistor structure 106. The source/drain electrodes 110 and 112 may be located at opposing ends of the channel layer 114.

The transistor structure 106 includes a gate electrode 116 and a gate dielectric layer 118 that are both included laterally adjacent to two or more sides of the channel layer 114 between the source/drain electrode 110 and 112. In some implementations, the gate electrode 116 and the gate dielectric layer 118 both laterally wrap around at least three sides of the channel layer 114, thereby providing greater gate control over the conductivity of the channel layer 114. In some implementations, the gate electrode 116 and the gate dielectric layer 118 both entirely laterally wrap around all sides of the channel layer 114, which provides further gate control over the conductivity of the channel layer 114. This may reduce current leakage between the source/drain electrodes 110 and 112 through the channel layer 114 and/or may increase drive current through the channel layer 114.

In some implementations, a gate electrode 116 extends as a column in the y-direction in the semiconductor device 100 and is electrically connected to a plurality of transistor structures 106 in a column of memory cell structures 104 in the memory array 102. Each transistor structure 106 of the memory cell structures 104 may include a gate dielectric layer 118 between the gate electrode and the channel layer 114, and that wraps around two or more sides of the channel layer 114.

As further shown in FIG. 1, hydrogen-blocking columns 120 are included along, and laterally adjacent to, one or more sides of a gate electrode 116 of a transistor structure 106 of a memory cell structure 104. The hydrogen-blocking columns 120 may be included laterally adjacent to the gate electrodes 116 of the transistor structures 106 in the memory array 102 to prevent, minimize, and/or reduce the diffusion of hydrogen from other layers and/or structures int the semiconductor device 100 into the channel layers 114 (e.g., through the gate electrodes 116). The hydrogen-blocking columns 120 may extend in the y-direction alongside the gate electrodes 116 and one or more of the hydrogen-blocking columns 120 are located between adjacent gate electrodes 116. In other words, the hydrogen-blocking columns 120 and the gate electrodes 116 may each extend in the y-direction and may be arranged in an alternating manner in the x-direction in the memory array 102. Thus, hydrogen-blocking columns 120 may be located alongside a gate electrode 116 and may extend along opposing sides of the gate electrode 116. The hydrogen-blocking columns 120 may continuously extend in the y-direction alongside the gate electrodes 116 (e.g., as opposed to being composed of a plurality of non-continuous segments) so that the hydrogen-blocking columns 120 provide hydrogen diffusion blocking along the full length of the gate electrodes 116.

In some implementations, the hydrogen-blocking columns 120 are discrete columns that are not connected together. In some implementations, the hydrogen-blocking columns 120 are connected together at ends of the hydrogen-blocking columns 120 by a connection section 120a. In these implementations, the combination of the hydrogen-blocking columns 120 and the connection sections 120a may surround the gate electrodes 116 in the memory array 102 to provide hydrogen diffusion blocking along all lateral sides of the gate electrodes 116.

Additionally, the hydrogen-blocking columns 120 along the sides of the gate electrode 116 may have bottom surfaces that are approximately co-planar with the bottom surface of the gate electrode 116, and may have top surfaces that are approximately co-planar with the top surface of the gate electrode 116. This may result from the hydrogen-blocking columns 120 being used as a self-aligned mask to form the gate electrode 116, and/or from the hydrogen-blocking columns 120 and the gate electrode 116 being planarized in the same planarization operation.

In some implementations, a hydrogen-blocking column 120 may have a lateral width (indicated in FIG. 1 as dimension D1) that is included in a range of approximately 10 nanometers to approximately 100 nanometers. If the lateral width of the hydrogen-blocking column 120 is less than approximately 10 nanometers, the hydrogen-blocking column 120 may not effectively block hydrogen diffusion into the channel layers 114. Moreover, the likelihood of the hydrogen-blocking column 120 collapsing (e.g., due to stresses from planarization and/or other processing operations) increases at lateral widths of less than approximately 10 nanometers. If the lateral width of the hydrogen-blocking column 120 is greater than approximately 100 nanometers, the hydrogen-blocking column 120 may occupy too large of a space in the memory array 102 to enable a sufficient density of memory cell structures 104 to be achieved. Alternatively, the lateral size of the gate electrodes 116 may be reduced to accommodate the larger size of the hydrogen-blocking columns 120, resulting in reduced channel control and/or increased channel leakage. If the lateral width of the hydrogen-blocking column 120 is included in the range of approximately 10 nanometers to approximately 100 nanometers, the hydrogen-blocking column 120 may effectively block hydrogen diffusion into the channel layers 114 with minimal likelihood of collapsing, while still enabling a high density of memory cell structures 104 to be achieved in the memory array 102. However, other values, and ranges other than approximately 10 nanometers to approximately 100 nanometers, are within the scope of the present disclosure.

The source/drain electrode 112 of a transistor structure 106 of a memory cell structure 104 may be electrically coupled with a bit line conductive structure 122 above the source/drain electrode 112 in the z-direction. The bit line conductive structures 122 may extend in the x-direction in the semiconductor device 100 and may be approximately perpendicular to the hydrogen-blocking columns 120 in the memory array 102. In some implementations, the source/drain electrodes 112 of the transistor structures 106 included in the same x-direction row in the memory array 102 may be electrically coupled to the same bit line conductive structure 122. The bit line conductive structures 122 may each include a metallization layer, a trench, a conductive trace, and/or another type of conductive structure.

A memory cell structure 104 may include a source/drain interconnect structure 124 that electrically couples the storage structure 108 of the memory cell structure 104 and the source/drain electrode 110 of the transistor structure 106 of the memory cell structure 104. The source/drain interconnect structure 124 may include a via, a column, a pillar, and/or another type of elongated structure in the z-direction. The source/drain interconnect structure 124 may be located below the source/drain electrode 110 and above the storage structure 108 in the z-direction.

The gate electrode 116 of a transistor structure 106 of a memory cell structure 104 may be electrically coupled and/or physically coupled with a word line interconnect structure 126. The word line interconnect structure 126 electrically couples the gate electrode 116 with a word line conductive structure 128 in the memory array 102. The word line interconnect structure 126 may include a via, a column, a pillar, and/or another type of elongated structure in the z-direction. The word line interconnect structure 126 may be located vertically between the gate electrode 116 and the word line conductive structure 128 in the z-direction. The word line conductive structure 128 may extend in the y-direction in the semiconductor device 100, which is approximately parallel to the hydrogen-blocking columns 120. The word line conductive structure 128 may include a metallization layer, a trench, a conductive trace, and/or another type of elongated conductive structure.

In some implementations, the gate electrodes 116 of the transistor structures 106 included in the same y-direction column in the memory array 102 may be electrically coupled to the same word line conductive structure 128. The bit line conductive structures 122 and the word line conductive structures 128 may each be coupled with circuitry, including control circuitry, a read buffer, a write buffer, and/or another type of circuitry in the semiconductor device 100.

As indicated above, FIG. 1 is provided as an example. Other examples may differ from what is described with regard to FIG. 1.

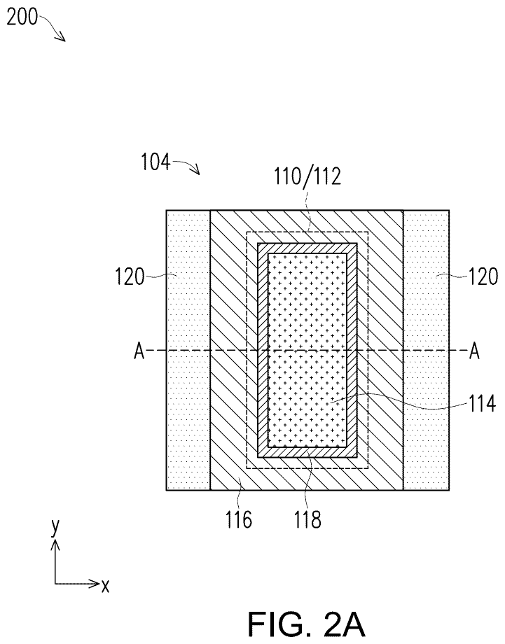

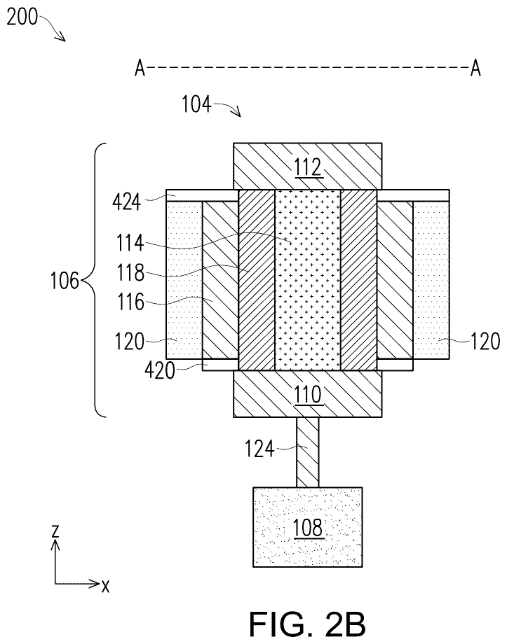

FIGS. 2A and 2B are diagrams of an example implementation 200 of a memory cell structure 104 described herein. FIG. 2A is a top view of the example implementation 200 of the memory cell structure 104, and FIG. 2B is a cross-section view along the line A-A in FIG. 2A.

As shown in FIG. 2A, the gate electrode 116 of the transistor structure 106 of the memory cell structure 104 may laterally surround the channel layer 114. The gate dielectric layer 118 of the transistor structure 106 of the memory cell structure 104 may also laterally surround the channel layer 114 and may be included between the channel layer 114 and the gate electrode 116. Hydrogen-blocking columns 120 may be included along and laterally adjacent to opposing sides of the gate electrode 116. In some implementations, a connection section 120a is located laterally adjacent to an end of the gate electrode 116 and connects the hydrogen-blocking columns 120 that are included along the opposing sides of the gate electrode 116.

As shown in FIG. 2B, the channel layer 114 extends vertically between the source/drain electrodes 110 and 112. The storage structure 108 is located vertically below the transistor structure 106 and is electrically coupled to the source/drain electrode 110 of the transistor structure 106 through a source/drain interconnect structure 124.

The source/drain electrodes 110 and 112 may each include polysilicon, indium tin oxide (ITO), copper (Cu), cobalt (Co), ruthenium (Ru), titanium (Ti), tungsten (W), and/or aluminum (Al), tantalum nitride (TaN), titanium nitride (TiN), and/or another electrically conductive material, among other examples.

The channel layer 114 may include a semiconductor material such as silicon (Si), doped silicon, germanium (Ge), silicon germanium (SiGe), a III-V semiconductor compound, and/or another semiconductor material. Additionally and/or alternatively, the channel layer 114 may include an oxide-semiconductor material. Thus, the transistor structure 106 may be referred to as an oxide-semiconductor field effect transistor (OSFET). In some implementations, the channel layer 114 includes an n-type oxide-semiconductor material such as indium gallium zinc oxide (InGaZnO or IGZO), zinc oxide (ZnO), indium oxide (InₓO_{y} such as In₂O₃), tin dioxide (SnO₂), among other examples. In some implementations, the channel layer 114 includes a p-type oxide-semiconductor material such as nickel oxide (NiO), copper oxide (CuₓO such as Cu₂O), copper aluminum oxide (CuAlOₓ such as CuAlO₂), copper gallium oxide (CuGaOₓ such as CuGaO₂), copper indium oxide (CuInOₓ such as CuInO₂), strontium copper oxide (SrCuₓO_{y} such as SrCu₂O₂), and/or tin oxide (SnO), among other examples.

The gate electrode 116 may include polysilicon, indium tin oxide (ITO), copper (Cu), cobalt (Co), ruthenium (Ru), titanium (Ti), tungsten (W), and/or aluminum (Al), tantalum nitride (TaN), titanium nitride (TiN), and/or another electrically conductive material, among other examples.

The gate dielectric layer 118 may include one or more dielectric materials. In some implementations, the gate dielectric layer 118 includes one or more low dielectric constant (low-k) dielectric materials (e.g., a dielectric material having a dielectric constant of approximately 3.9 or less), such as a silicon oxide (SiOₓ such as SiO₂), undoped silicate glass (USG), and/or fluoride-doped silicate glass (FSG), among other examples. In some implementations, the gate dielectric layer 118 includes one or more high dielectric constant (high-k) dielectric materials (e.g., a dielectric material having a dielectric constant of greater than approximately 3.9), such as a silicon nitride (SiₓN_{y} such as Si₃N₄), a silicon oxynitride (SiON), a hafnium oxide (HfOₓ such as HfO₂), an aluminum oxide (AlₓO_{y} such as Al₂O₃), a lanthanum oxide (LaₓO_{y} such as La₂O₃), zirconium oxide (ZrOₓ such as ZrO₂), and/or an yttrium oxide (YₓO_{y} such as Y₂O₃), among other examples.

The hydrogen-blocking columns 120 may each include one or more materials that inhibit the diffusion of hydrogen (H) into and/or through the hydrogen-blocking columns 120. Such materials may have strong chemical bonds (e.g., covalent bonds and/or ionic bonds) between the elements of the material, which provides a stable barrier against the diffusion of hydrogen. Additionally and/or alternatively, such materials may have high density, low porosity, and/or a crystalline structure, which may result in low permeability for hydrogen. Examples of materials for the hydrogen-blocking columns 120 include a silicon nitride (SiₓN_{y} such as Si₃N₄), silicon oxynitride (SiON), an aluminum oxide (AlₓO_{y} such as Al₂O₃), silicon carbonitride (SiCN), silicon carbon oxynitride (SiCON), aluminum nitride (AlN), aluminum oxynitride (AlON), another nitride-containing dielectric material, and/or another oxide-containing dielectric material, among other examples.

As indicated above, FIGS. 2A and 2B are provided as an example. Other examples may differ from what is described with regard to FIGS. 2A and 2B.

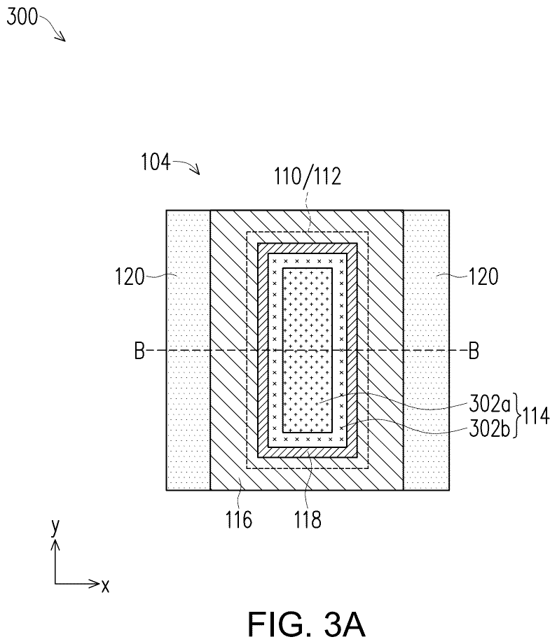

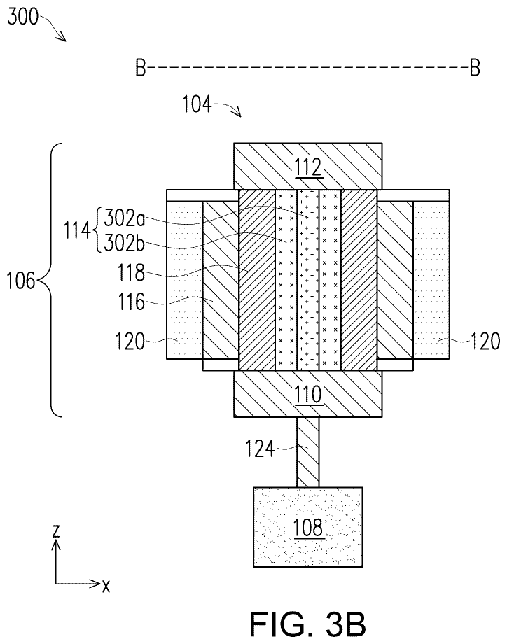

FIGS. 3A and 3B are diagrams of an example implementation 300 of a memory cell structure 104 described herein. FIG. 3A is a top view of the example implementation 300 of the memory cell structure 104, and FIG. 3B is a cross-section view along the line B-B in FIG. 3A.

As shown in FIGS. 3A and 3B, the example implementation 300 of the memory cell structure 104 is similar to the example implementation 200 of the memory cell structure 104 illustrated in FIGS. 2A and 2B. However, the transistor structure 106 in the example implementation 300 of the memory cell structure 104 includes a multiple-layer channel layer 114. As shown in FIG. 3A, the channel layer 114 of the transistor structure 106 in the example implementation 300 of the memory cell structure 104 includes a core section 302a and an outer section 302b wrapped around the core section 302a. The outer section 302b is in between the core section 302a and the gate dielectric layer 118. As shown in FIG. 3B, the core section 302a and the outer section 302b may both fully and continuously extend between the source/drain electrodes 110 and 112 in the z-direction. Thus, both the core section 302a and the outer section 302b may be in physical contact with the source/drain electrodes 110 and 112 at opposing ends of the core section 302a and opposing ends of the outer section 302b.

The core section 302a and the outer section 302b may include different materials. For example, the core section 302a and the outer section 302b may include different semiconductor materials, different oxide-semiconductor materials, and/or different material compositions, and/or other examples. In some implementations, the core section 302a includes a first semiconductor material having a first dopant concentration, and the outer section 302b includes a second semiconductor material (e.g., the same semiconductor material as the first semiconductor material or a different semiconductor material from the first semiconductor material) having a second dopant concentration that is different from the first dopant concentration. In some implementations, the core section 302a includes a first oxide-semiconductor material having a first dopant concentration, and the outer section 302b includes a second oxide-semiconductor material (e.g., the same oxide-semiconductor material as the first oxide-semiconductor material or a different oxide-semiconductor material from the first oxide-semiconductor material) having a second dopant concentration that is different from the first dopant concentration.

In some implementations, the oxide-semiconductor materials of the core section 302a and of the outer section 302b may include the same dopant such as indium (In). In some implementations, the oxide-semiconductor materials of the core section 302a and of the outer section 302b may include different dopants. The second dopant concentration in the outer section 302b may be greater than the first dopant concentration in the core section 302a to provide greater carrier transport performance (and thus, increased gate control) in the outer section 302b, whereas the lower dopant concentration in the core section 302a provides increased resistance to threshold voltage shifting in the core section 302a. In some implementations, the first dopant concentration in the core section 302a is included in a range of approximately 1×10¹⁴ dopant atoms (e.g., indium atoms) per cubic centimeter to approximately 1×10¹⁸ dopant atoms per cubic centimeter, and the second dopant concentration in the outer section 302b is included in a range of approximately 1×10¹⁷ dopant atoms (e.g., indium atoms) per cubic centimeter to approximately 1×10²¹ dopant atoms per cubic centimeter. However, other values and ranges for the first dopant concentration in the core section 302a and for the second dopant concentration in the outer section 302b are within the scope of the present disclosure.

As indicated above, FIGS. 3A and 3B are provided as an example. Other examples may differ from what is described with regard to FIGS. 3A and 3B.

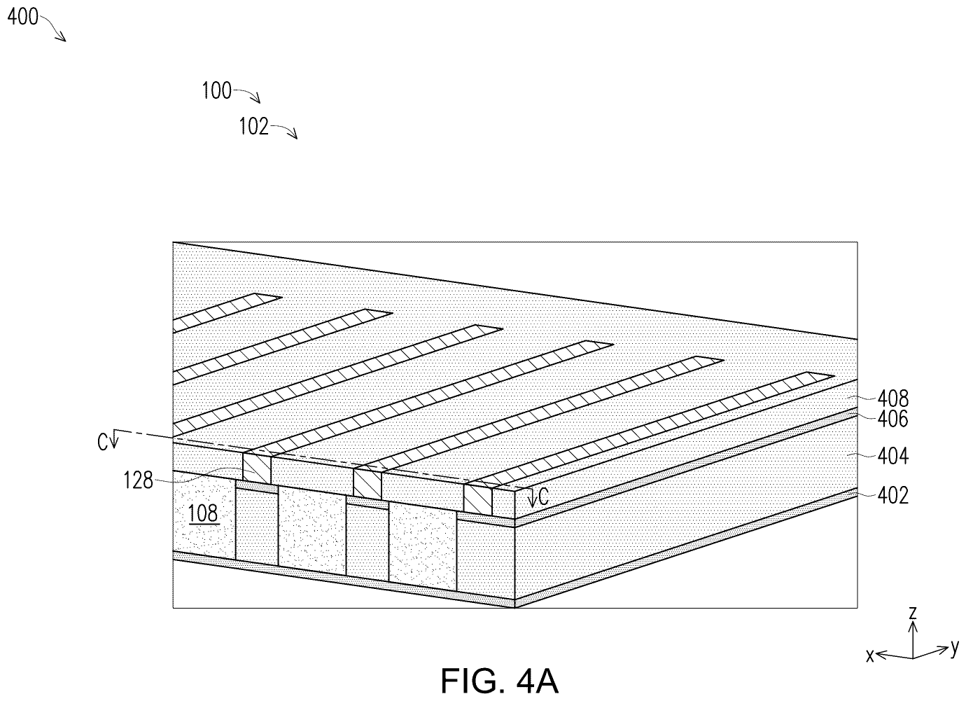

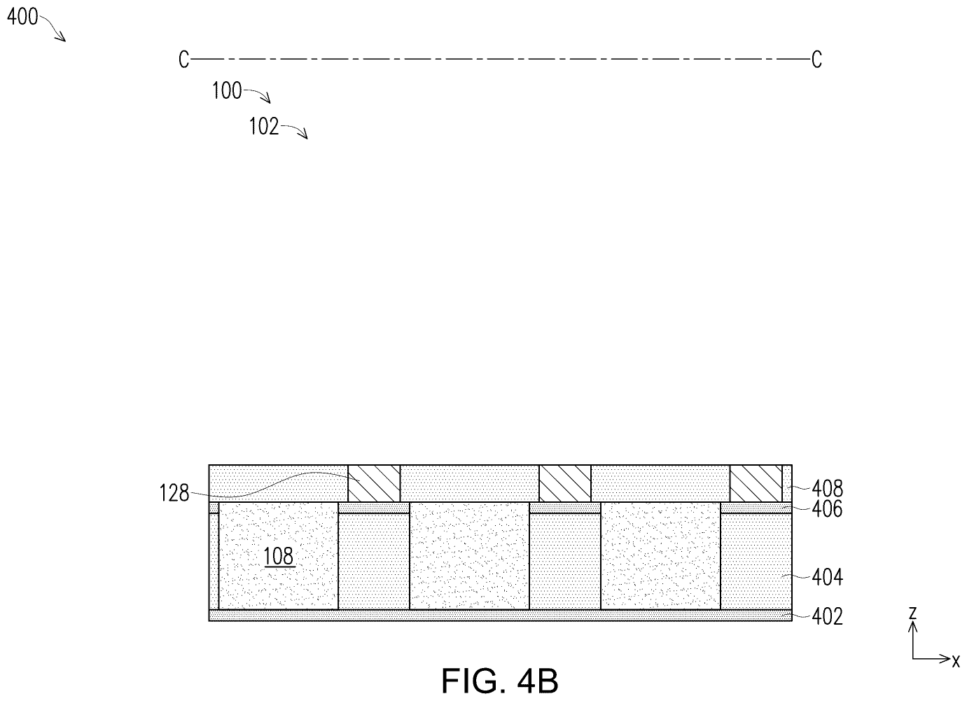

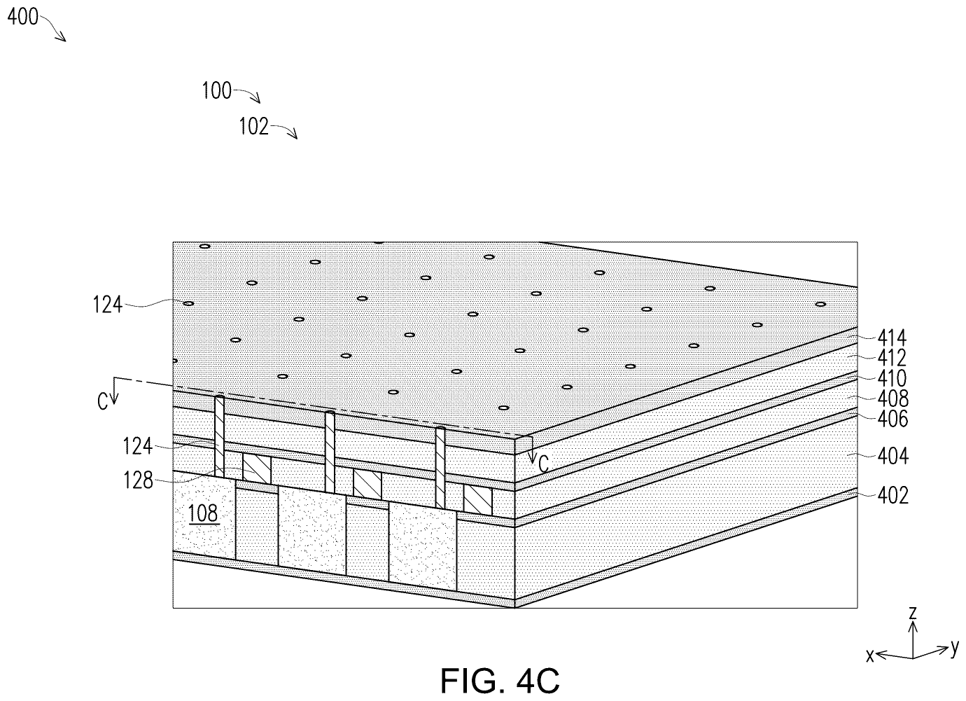

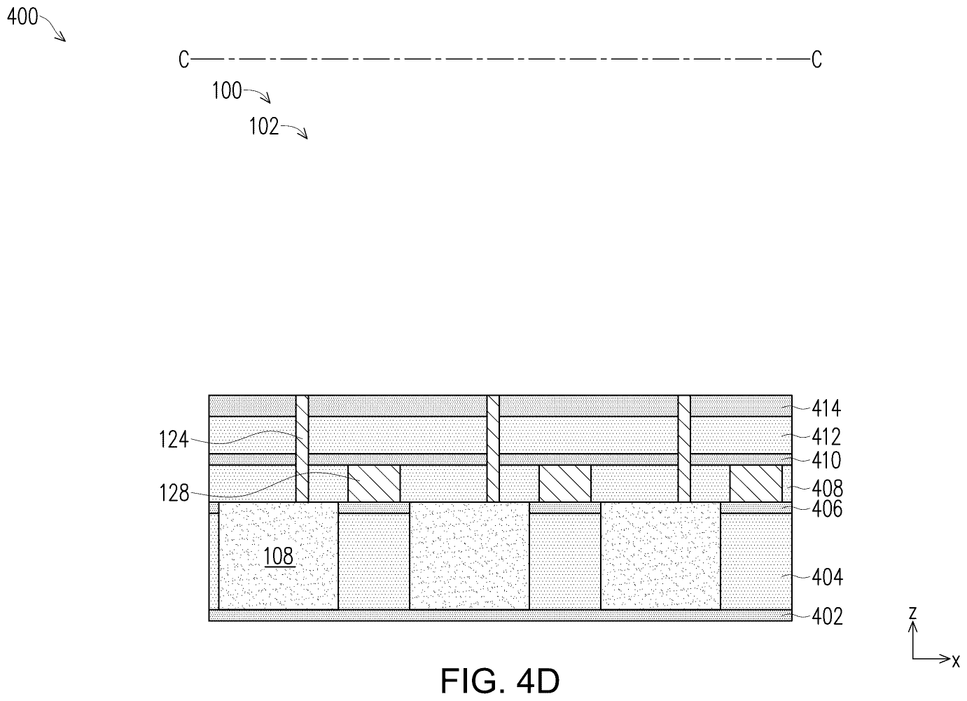

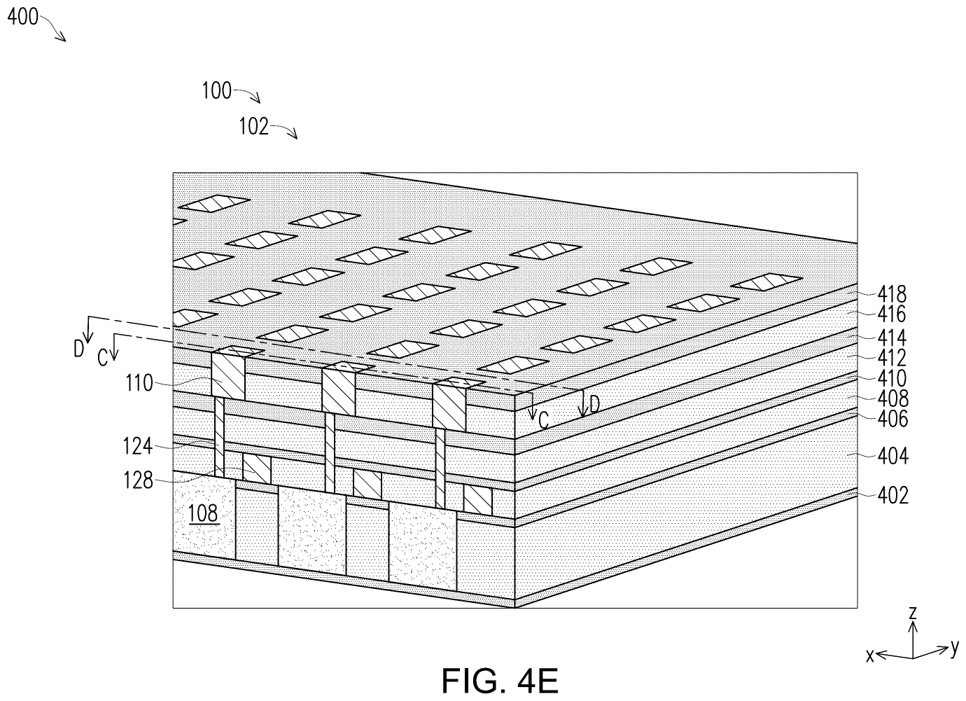

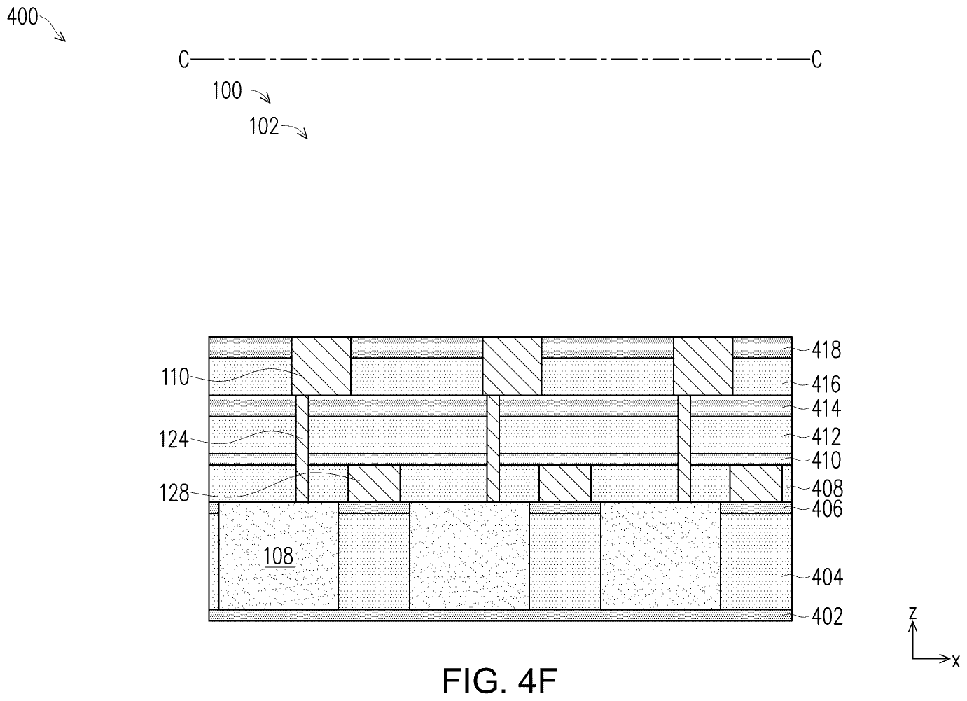

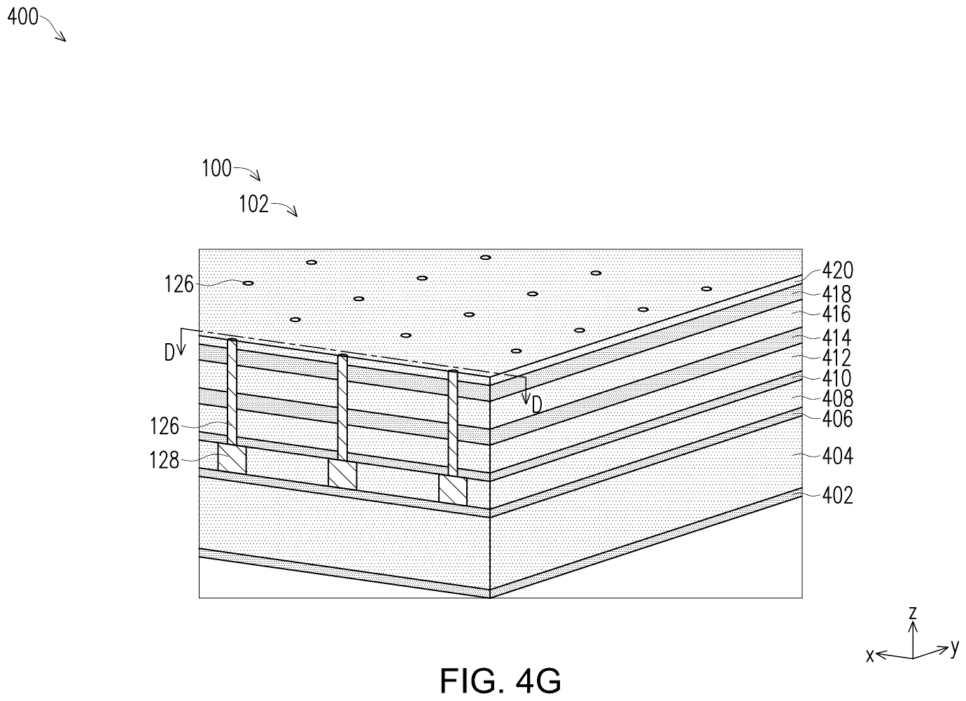

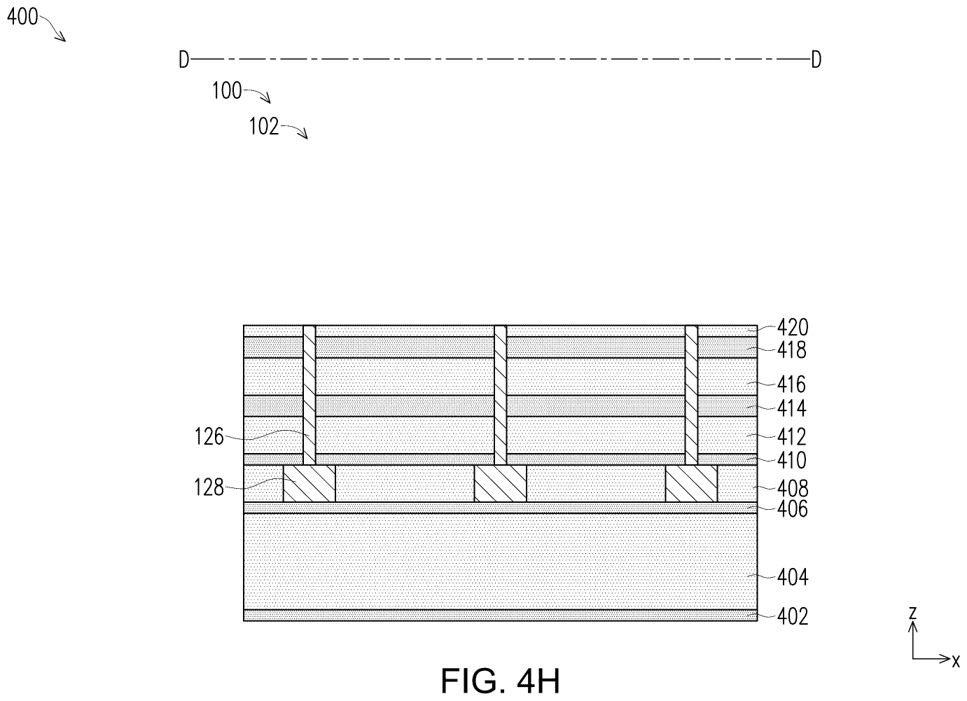

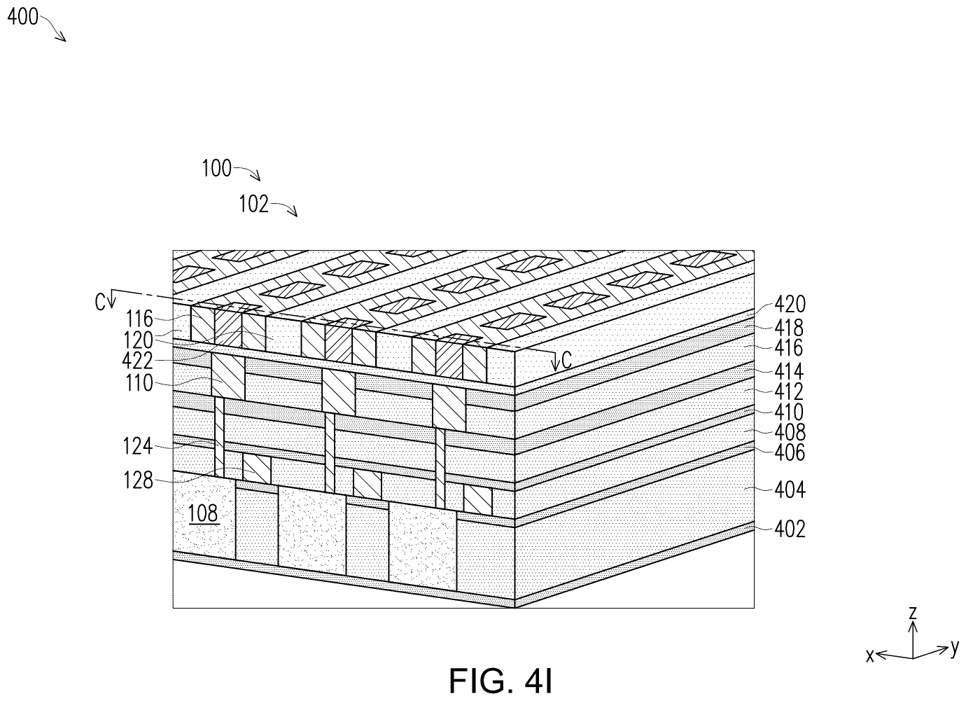

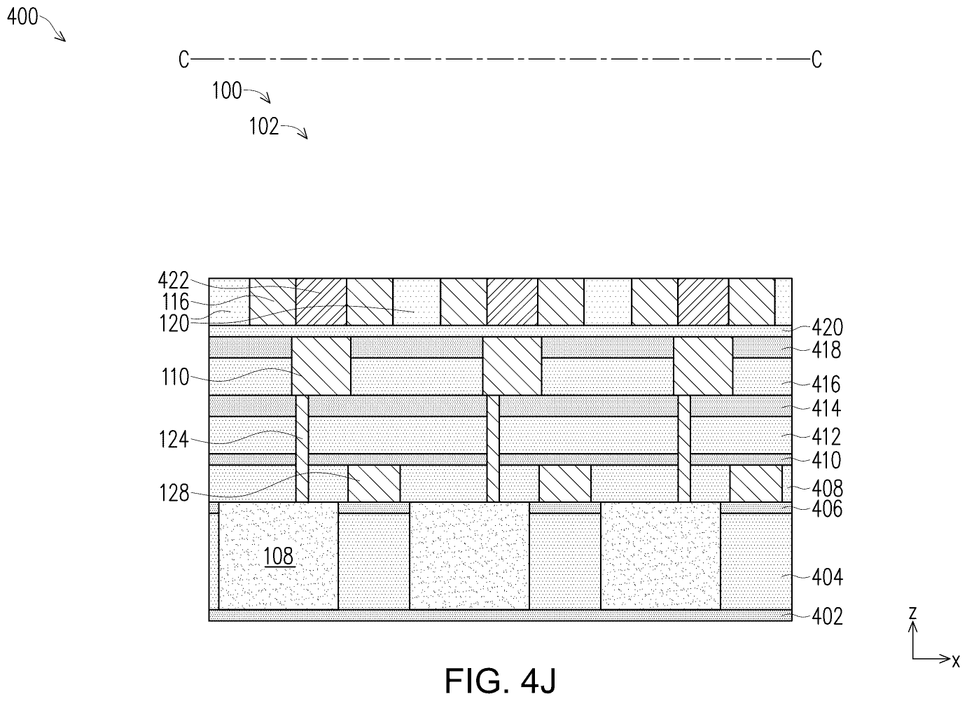

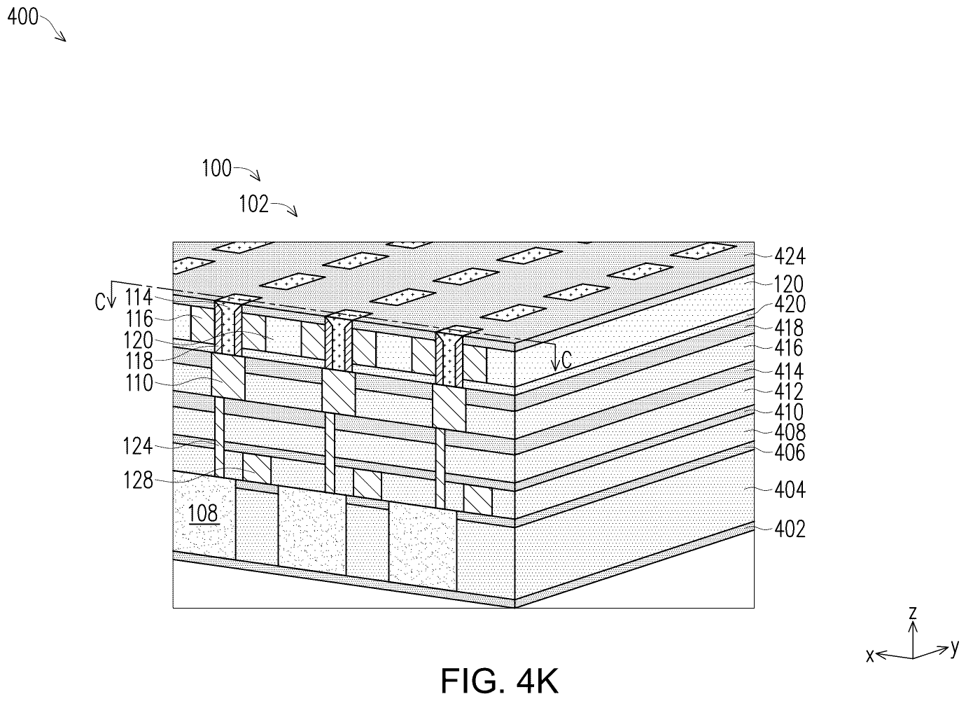

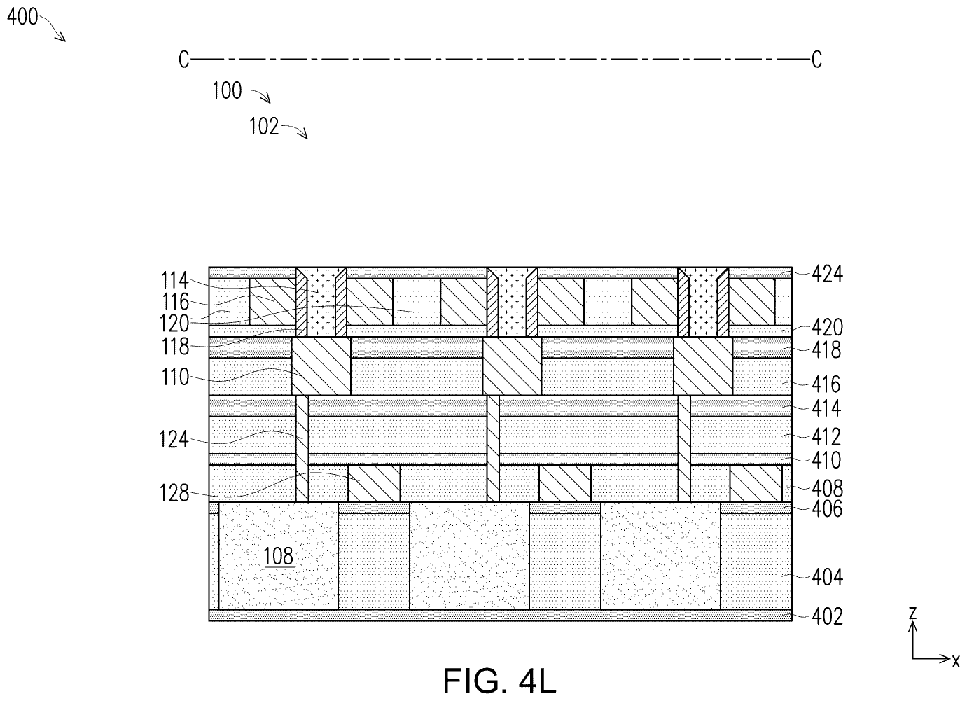

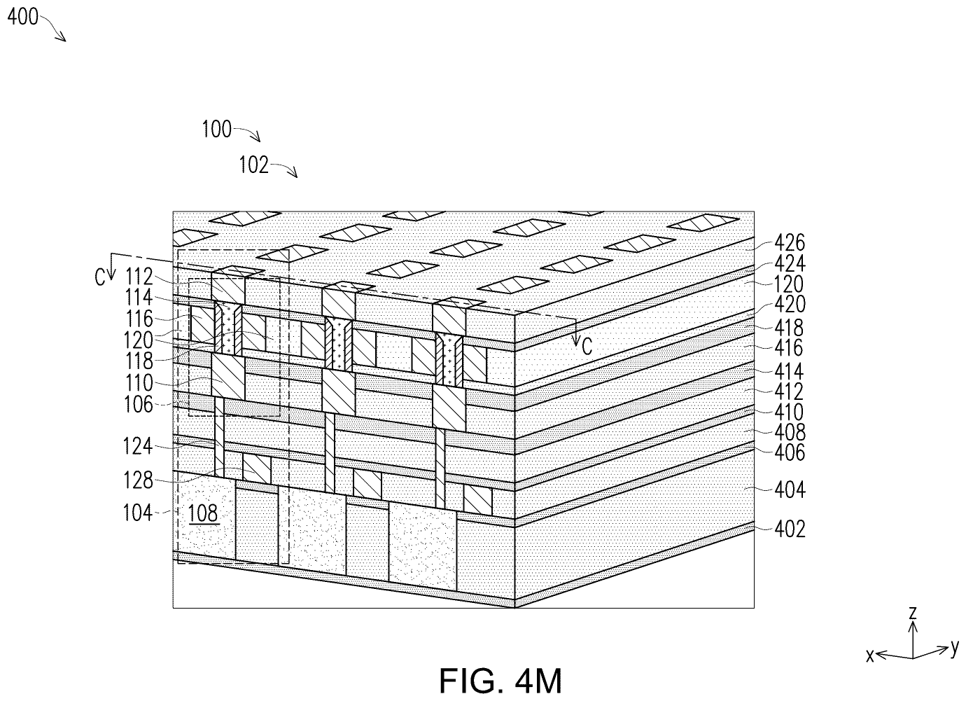

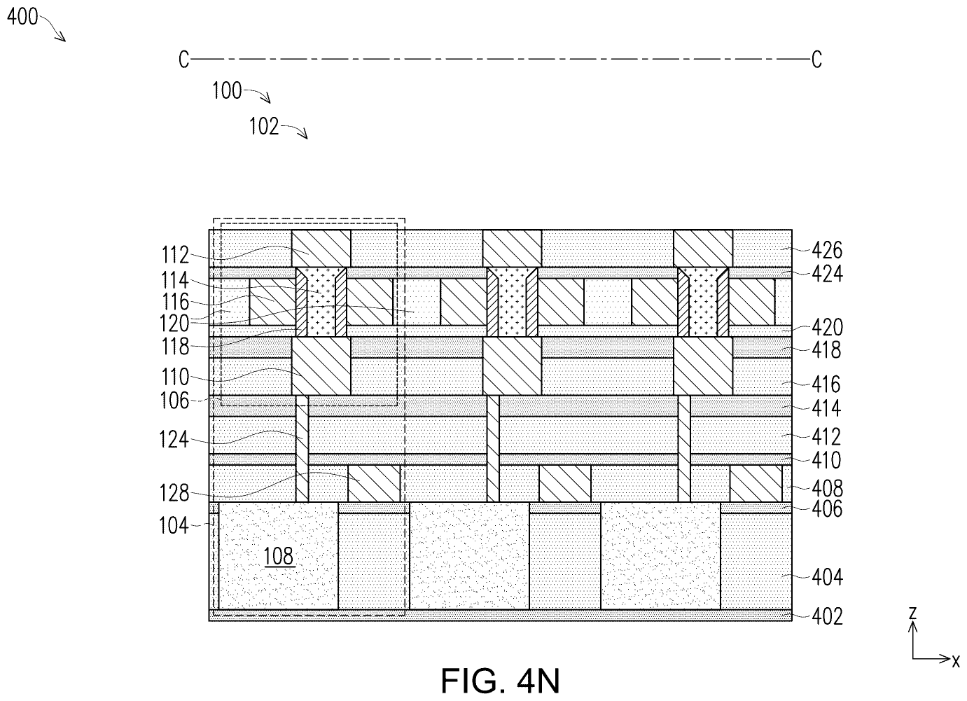

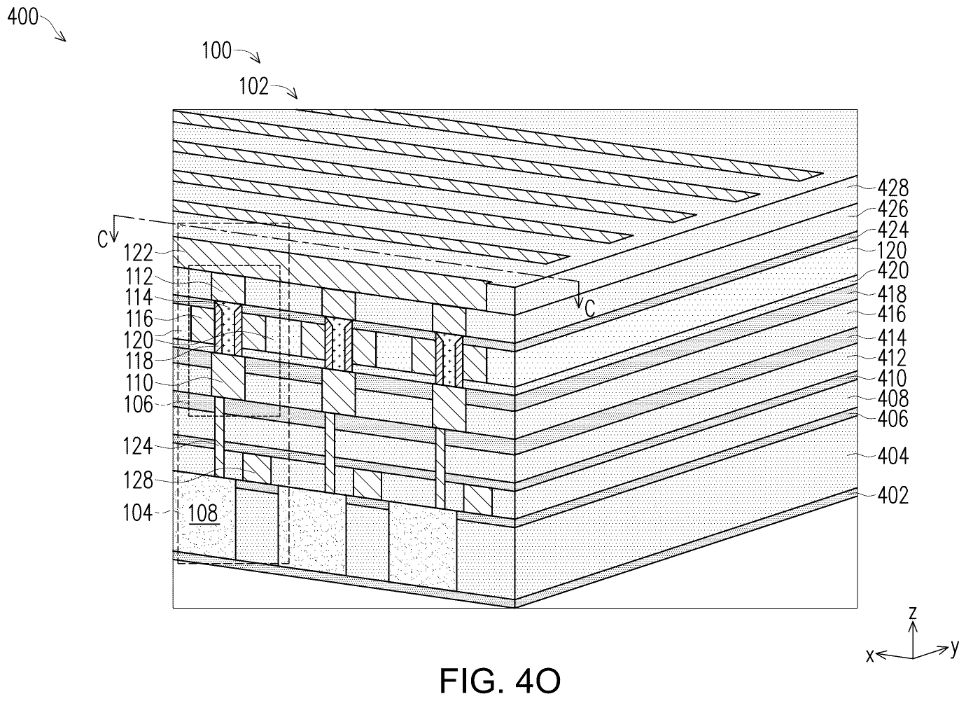

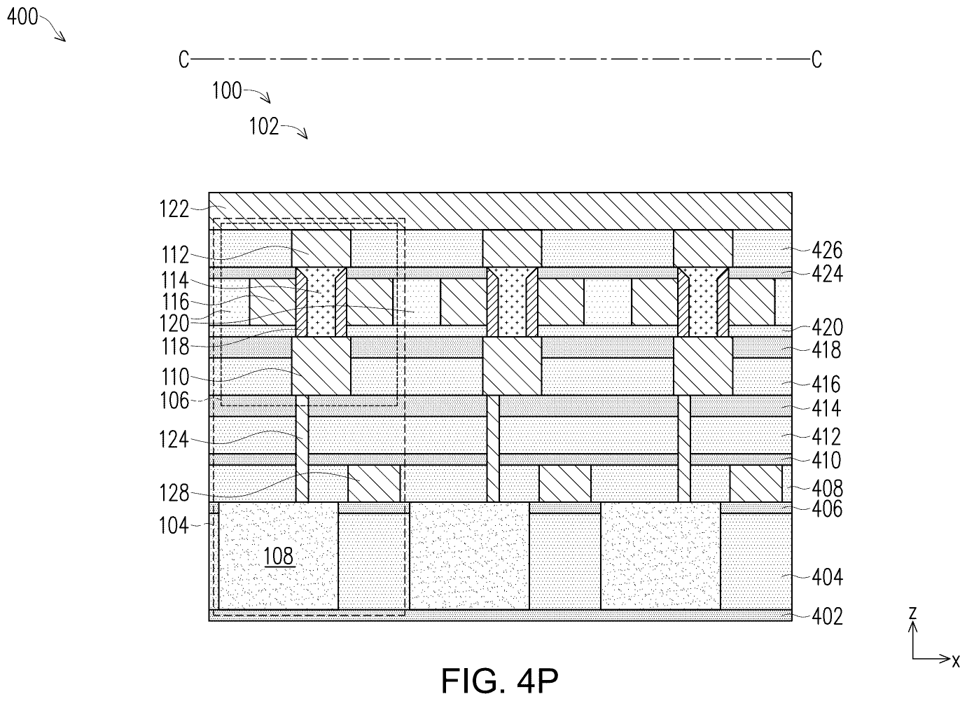

FIGS. 4A-4P are diagrams of an example implementation 400 of forming a memory array 102 of a semiconductor device 100 described herein. The memory array 102 may be formed to include a plurality of memory cell structures 104 and hydrogen-blocking columns 120 to prevent, minimize, and/or otherwise reduce hydrogen diffusion in the memory cell structures 104. In some implementations, one or more of the semiconductor processing operations described in connection with FIGS. 4A-4P may be performed using one or more semiconductor processing tools, such as a deposition tool, an exposure tool, a developer tool, an etch tool, a planarization tool, and/or an ion implantation tool, among other examples.

FIG. 4A illustrates a perspective view of the semiconductor device 100, and FIG. 4B illustrates a cross-section view along the line C-C (e.g., along the x-direction) in FIG. 4A. As shown in FIGS. 4A and 4B, various dielectric layers may be formed in the semiconductor device 100. For example, an etch stop layer (ESL) 402 may be formed, an interlayer dielectric (ILD) layer 404 may be formed above and/or on the ESL 402, another ESL 406 may be formed above and/or on the ILD layer 404, and another ILD layer 408 may be formed above and/or on the ESL 406. The ESLs 402, 406, and the ILD layers 404, 408 may be formed in a backend region (or interconnect layer) of the semiconductor device 100, and may therefore be referred to as backend dielectric layers. The ESLs 402, 406, and the ILD layers 404, 408 may each extend in the x-direction and in the y-direction, and may be arranged in the z-direction. The ESLs 402, 406, and the ILD layers 404, 408 may each include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material.

A deposition tool may be used to deposit the ESLs 402, 406, and the ILD layers 404, 408 using one or more deposition techniques, such as a physical vapor deposition (PVD) technique, an atomic layer deposition (ALD) technique, a chemical vapor deposition (CVD) technique, an oxidation technique, and/or another suitable deposition technique. The ESLs 402, 406, and the ILD layers 404, 408 may be deposited in one or more deposition operations. In some implementations, a planarization tool may be used to perform a planarization operation (e.g., a chemical mechanical planarization (CMP) operation) to planarize the ESLs 402, 406, and the ILD layers 404, 408 after the ESLs 402, 406, and the ILD layers 404, 408 are deposited.

As further shown in FIGS. 4A and 4B, the storage structures 108 of the memory cell structures 104 in the memory array 102 may be formed through the ESL 406 and into the ILD layer 404. For example, the ESL 402, the ILD layer 404, and the ESL 406 may be formed; recesses may be formed in and/or through the ESL 406 and the ILD layer 404 (e.g., such that the recesses stop on the ESL 402), and the storage structures 108 may be formed in the recesses. The ILD layer 408 may be formed after formation of the storage structures 108.

In some implementations, a pattern in a photoresist layer is used to etch the ESL 406 and the ILD layer 404 to form the recesses in the ESL 406 and the ILD layer 404. In these implementations, a deposition tool may be used to form the photoresist layer on the ESL 406 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the ESL 406 and the ILD layer 404 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ESL 406 and the ILD layer 404 based on a pattern to form the recesses.

In some implementations, forming a storage structure 108 in a recess includes forming a capacitor structure in the ILD layer 404. The capacitor structure may include a thin film capacitor structure (e.g., a planar capacitor structure), a DTC structure, and/or another type of capacitor structure. The capacitor structure may have a metal-insulator-metal (MIM) arrangement in which a bottom electrode and a top electrode are separated by an insulator layer. Additionally and/or alternatively, forming a storage structure 108 may include forming a phase-change material structure, forming a resistive structure, forming a ferroelectric structure, and/or forming another type of storage structure.

As further shown in FIGS. 4A and 4B, the word line conductive structures 128 of the memory array 102 may be formed in the ILD layer 408. Thus, the word line conductive structures 128 may be formed above the storage structures 108 of the memory cell structures 104 of the memory array 102. Forming the word line conductive structures 128 may include forming recesses in the ILD layer 408, and forming the word line conductive structures 128 in the recesses. In some implementations, one or more liners are first formed in the recesses, and the word line conductive structures 128 are formed on the liner(s). The liner(s) may include adhesion liners (e.g., liners that are included to promote adhesion between the word line conductive structures 128 and the surrounding layers such as the ILD layer 408 and/or the ESL 406), barrier layers (e.g., layers that are included to reduce or minimize diffusion of the material from the word line conductive structures 128 into the surrounding layers such as the ILD layer 408 and/or the ESL 406), and/or another type of liner. Examples of materials for the liner(s) include tantalum nitride (TaN) and/or titanium nitride (TiN), among other examples.

In some implementations, an etch tool is used to etch the ILD layer 408 to form the recesses (e.g., the trenches) in which the word line conductive structures 128 are to be formed. The recesses may extend in the y-direction in the semiconductor device 100. A deposition tool may be used to deposit the liner(s) using an ALD technique, a CVD technique, and/or another type of conformal deposition technique. A deposition tool may be used to deposit the word line conductive structures 128 using a CVD technique, a PVD technique, an ALD technique, an electroplating technique, and/or another suitable deposition technique. The word line conductive structures 128 may extend in the y-direction in the semiconductor device 100 and may be arranged in the x-direction in the semiconductor device 100. In some implementations, a seed layer is first deposited on the liner(s), and the word line conductive structures 128 are deposited on the seed layer. In some implementations, a planarization tool is used to perform a planarization operation (e.g., a CMP operation) to planarize the word line conductive structures 128 after the word line conductive structures 128 are formed. The top surfaces of the word line conductive structures 128 may be approximately co-planar with the top surface of the ILD layer 408 after the planarization operation.

FIG. 4C illustrates another perspective view of the semiconductor device 100, and FIG. 4D illustrates a cross-section view along the line C-C (e.g., along the x-direction) in FIG. 4C. As shown in FIGS. 4C and 4D, additional dielectric layers (e.g., additional backend dielectric layers) may be formed in the semiconductor device 100. For example, another ESL 410 may be formed on the ILD layer 408 and on the word line conductive structures 128, another ILD layer 412 may be formed above and/or on the ESL 410, and another ESL 414 may be formed above and/or on the ILD layer 412. The ESLs 410, 414, and the ILD layer 412 may each extend in the x-direction and in the y-direction, and may be arranged in the z-direction. The ESLs 410, 414, and the ILD layer 412 may each include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material.

A deposition tool may be used to deposit the ESLs 410, 414, and the ILD layer 412 using one or more deposition techniques, such as a PVD technique, an ALD technique, a CVD technique, an oxidation technique, and/or another suitable deposition technique. The ESLs 410, 414, and the ILD layer 412 may be deposited in one or more deposition operations. In some implementations, a planarization tool may be used to perform a planarization operation (e.g., a CMP operation) to planarize the ESLs 410, 414, and the ILD layer 412 after the ESLs 410, 414, and the ILD layer 412 are deposited.

As further shown in FIGS. 4C and 4D, the source/drain interconnect structures 124 may be formed through the ESL 414, the ILD layer 412, the ESL 410, and the ILD layer 408 such that the source/drain interconnect structures 124 land on the storage structures 108. In some implementations, a source/drain interconnect structure 124 is formed for each storage structure 108 in the memory array 102. In some implementations, a plurality of source/drain interconnect structures 124 are formed for a storage structure 108 in the memory array 102.

Forming the source/drain interconnect structures 124 may include forming recesses in and/or through the ESL 414, the ILD layer 412, the ESL 410, and the ILD layer 408, and forming the source/drain interconnect structures 124 in the recesses. In some implementations, a pattern in a photoresist layer is used to etch through the ESL 414, the ILD layer 412, the ESL 410, and the ILD layer 408 to form the recesses. In these implementations, a deposition tool may be used to form the photoresist layer on the ESL 414 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the ESL 414, the ILD layer 412, the ESL 410, and the ILD layer 408 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

In some implementations, one or more liners are first formed in the recesses, and the source/drain interconnect structures 124 are formed on the liner(s). The liner(s) may include adhesion liners (e.g., liners that are included to promote adhesion between the source/drain interconnect structures 124 and the surrounding layers such as the ESL 414, the ILD layer 412, the ESL 410, and/or the ILD layer 408), barrier layers (e.g., layers that are included to reduce or minimize diffusion of the material from the source/drain interconnect structures 124 into the surrounding layers such as the ESL 414, the ILD layer 412, the ESL 410, and/or the ILD layer 408), and/or another type of liner. Examples of materials for the liner(s) include tantalum nitride (TaN) and/or titanium nitride (TiN), among other examples. A deposition tool may be used to deposit the liner(s) in the recesses using an ALD technique, a CVD technique, and/or another type of conformal deposition technique.

A deposition tool may be used to deposit the source/drain interconnect structures 124 using a CVD technique, a PVD technique, an ALD technique, an electroplating technique, and/or another suitable deposition technique. The source/drain interconnect structures 124 may extend in the z-direction in the semiconductor device 100 and may land on the storage structures 108. In some implementations, a seed layer is first deposited on the liner(s), and the source/drain interconnect structures 124 are deposited on the seed layer. In some implementations, a planarization tool is used to perform a planarization operation (e.g., a CMP operation) to planarize the source/drain interconnect structures 124 after the source/drain interconnect structures 124 are formed. The top surfaces of the source/drain interconnect structures 124 may be approximately co-planar with the top surface of the ESL 414 after the planarization operation.

FIG. 4E illustrates another perspective view of the semiconductor device 100, and FIG. 4F illustrates a cross-section view along the line C-C (e.g., along the x-direction) in FIG. 4D. As shown in FIGS. 4E and 4F, additional dielectric layers (e.g., additional backend dielectric layers) may be formed in the semiconductor device 100. For example, another ILD layer 416 may be formed above and/or on the ESL 414, and another ESL 418 may be formed above and/or on the ILD layer 416. The ILD layer 416 and the ESL 418 may each extend in the x-direction and in the y-direction, and may be arranged in the z-direction. The ILD layer 416 and the ESL 418 may each include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material.

A deposition tool may be used to deposit the ILD layer 416 and the ESL 418 using one or more deposition techniques, such as a PVD technique, an ALD technique, a CVD technique, an oxidation technique, and/or another suitable deposition technique. The ILD layer 416 and the ESL 418 may be deposited in one or more deposition operations. In some implementations, a planarization tool may be used to perform a planarization operation (e.g., a CMP operation) to planarize the ILD layer 416 and the ESL 418 after the ILD layer 416 and the ESL 418 are deposited.

As further shown in FIGS. 4E and 4F, the source/drain electrodes 110 of the transistor structures 106 of the memory cell structures 104 may be formed through the ILD layer 416 and the ESL 418 such that the source/drain electrodes 110 land on the source/drain interconnect structures 124. Forming the source/drain electrodes 110 may include forming recesses in and/or through the ILD layer 416 and the ESL 418, and forming the source/drain electrodes 110 in the recesses. In some implementations, a pattern in a photoresist layer is used to etch through the ILD layer 416 and the ESL 418 to form the recesses. In these implementations, a deposition tool may be used to form the photoresist layer on the ESL 418 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the ILD layer 416 and the ESL 418 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

In some implementations, one or more liners are first formed in the recesses, and the source/drain electrodes 110 are formed on the liner(s). The liner(s) may include adhesion liners (e.g., liners that are included to promote adhesion between the source/drain electrodes 110 and the surrounding layers such as the ILD layer 416 and/or the ESL 418), barrier layers (e.g., layers that are included to reduce or minimize diffusion of the material from the source/drain electrodes 110 into the surrounding layers such as the ILD layer 416 and/or the ESL 418), and/or another type of liner. Examples of materials for the liner(s) include tantalum nitride (TaN) and/or titanium nitride (TiN), among other examples. A deposition tool may be used to deposit the liner(s) in the recesses using an ALD technique, a CVD technique, and/or another type of conformal deposition technique.

A deposition tool may be used to deposit the source/drain electrodes 110 using a CVD technique, a PVD technique, an ALD technique, an electroplating technique, and/or another suitable deposition technique. In some implementations, a seed layer is first deposited on the liner(s), and the source/drain electrodes 110 are deposited on the seed layer. In some implementations, a planarization tool is used to perform a planarization operation (e.g., a CMP operation) to planarize the source/drain electrodes 110 after the source/drain electrodes 110 are formed. The top surfaces of the source/drain electrodes 110 may be approximately co-planar with the top surface of the ESL 418 after the planarization operation.

FIG. 4G illustrates another perspective view of the semiconductor device 100, and FIG. 4H illustrates a cross-section view along the line D-D (e.g., along the x-direction) in FIG. 4G. As shown in FIGS. 4G and 4H, additional dielectric layers (e.g., additional backend dielectric layers) may be formed in the semiconductor device 100. For example, another ILD layer 420 may be formed above and/or on the ESL 418. The ILD layer 420 may extend in the x-direction and in the y-direction. The ILD layer 420 may include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material.

A deposition tool may be used to deposit the ILD layer 420 using one or more deposition techniques, such as a PVD technique, an ALD technique, a CVD technique, an oxidation technique, and/or another suitable deposition technique. The ILD layer 420 may be deposited in one or more deposition operations. In some implementations, a planarization tool may be used to perform a planarization operation (e.g., a CMP operation) to planarize the ILD layer 420 after the ILD layer 420 is deposited.

As further shown in FIGS. 4G and 4H, the word line interconnect structures 126 of the memory cell structures 104 may be formed through the ILD layer 420, through the ESL 418, through the ILD layer 416, through the ESL 414, through the ILD layer 412, and/or through the ESL 410 such that the word line interconnect structures 126 land on word line conductive structures 128. Forming the word line interconnect structures 126 may include forming recesses in and/or through the ILD layer 420, the ESL 418, the ILD layer 416, the ESL 414, the ILD layer 412, and/or the ESL 410, and forming the word line interconnect structures 126 in the recesses. In some implementations, a pattern in a photoresist layer is used to etch through the ILD layer 420, the ESL 418, the ILD layer 416, the ESL 414, the ILD layer 412, and/or the ESL 410 to form the recesses. In these implementations, a deposition tool may be used to form the photoresist layer on the ILD layer 420 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the ILD layer 420, the ESL 418, the ILD layer 416, the ESL 414, the ILD layer 412, and/or the ESL 410 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

In some implementations, one or more liners are first formed in the recesses, and the word line interconnect structures 126 are formed on the liner(s). The liner(s) may include adhesion liners (e.g., liners that are included to promote adhesion between the word line interconnect structures 126 and the surrounding layers such as the ILD layer 420, the ESL 418, the ILD layer 416, the ESL 414, the ILD layer 412, and/or the ESL 410), barrier layers (e.g., layers that are included to reduce or minimize diffusion of the material from the word line interconnect structures 126 into the surrounding layers such as the ILD layer 420, the ESL 418, the ILD layer 416, the ESL 414, the ILD layer 412, and/or the ESL 410), and/or another type of liner. Examples of materials for the liner(s) include tantalum nitride (TaN) and/or titanium nitride (TiN), among other examples. A deposition tool may be used to deposit the liner(s) in the recesses using an ALD technique, a CVD technique, and/or another type of conformal deposition technique.

A deposition tool may be used to deposit the word line interconnect structures 126 using a CVD technique, a PVD technique, an ALD technique, an electroplating technique, and/or another suitable deposition technique. In some implementations, a seed layer is first deposited on the liner(s), and the word line interconnect structures 126 are deposited on the seed layer. In some implementations, a planarization tool is used to perform a planarization operation (e.g., a CMP operation) to planarize the word line interconnect structures 126 after the word line interconnect structures 126 are formed. The top surfaces of the word line interconnect structures 126 may be approximately co-planar with the top surface of the ILD layer 420 after the planarization operation.

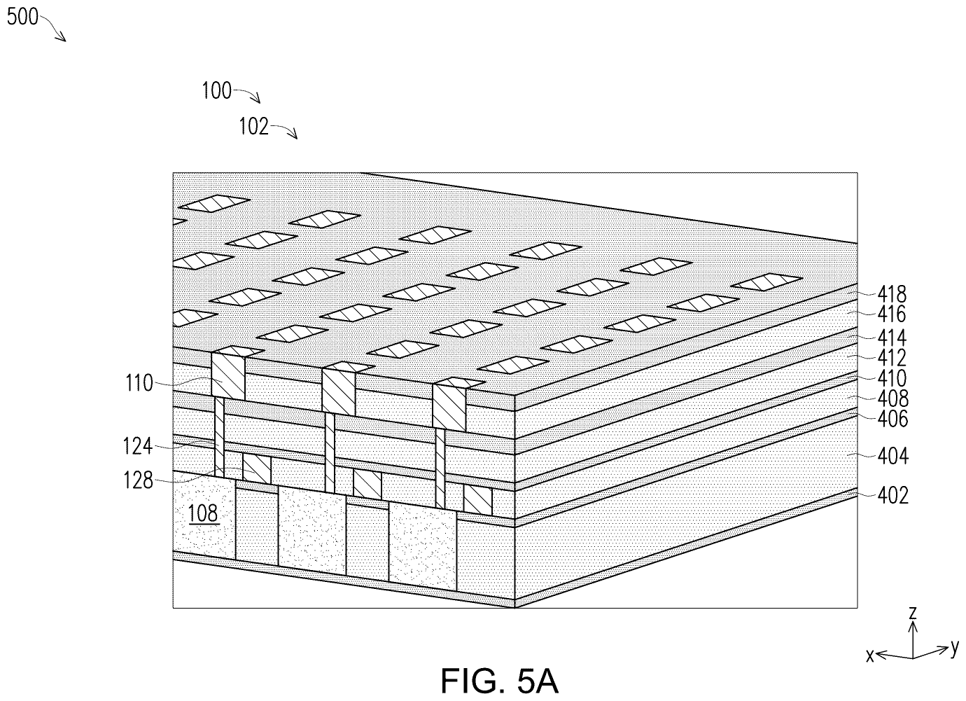

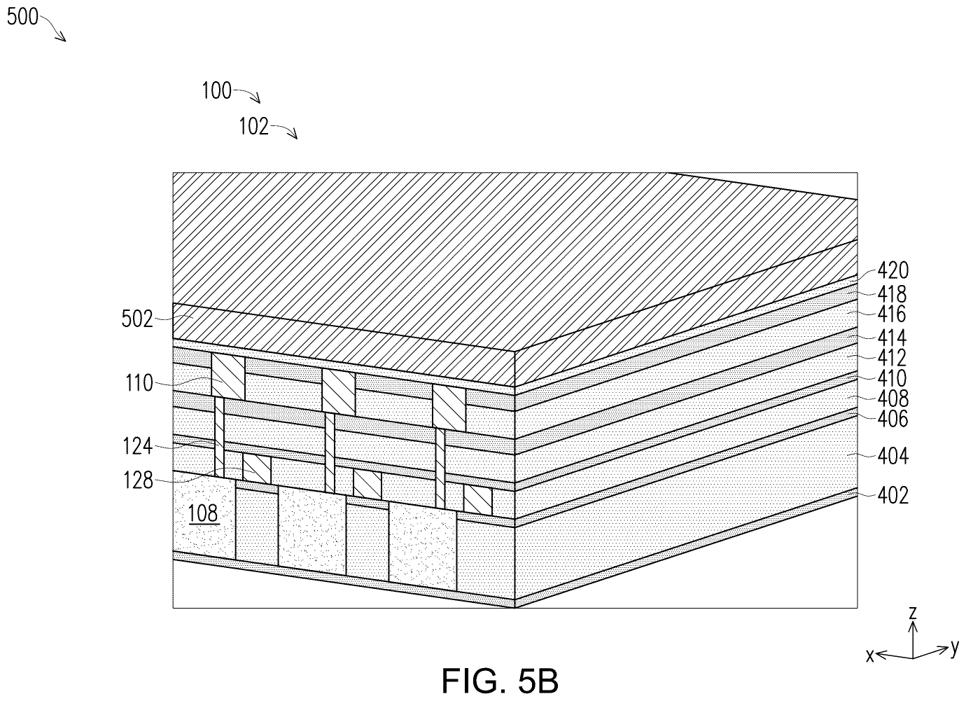

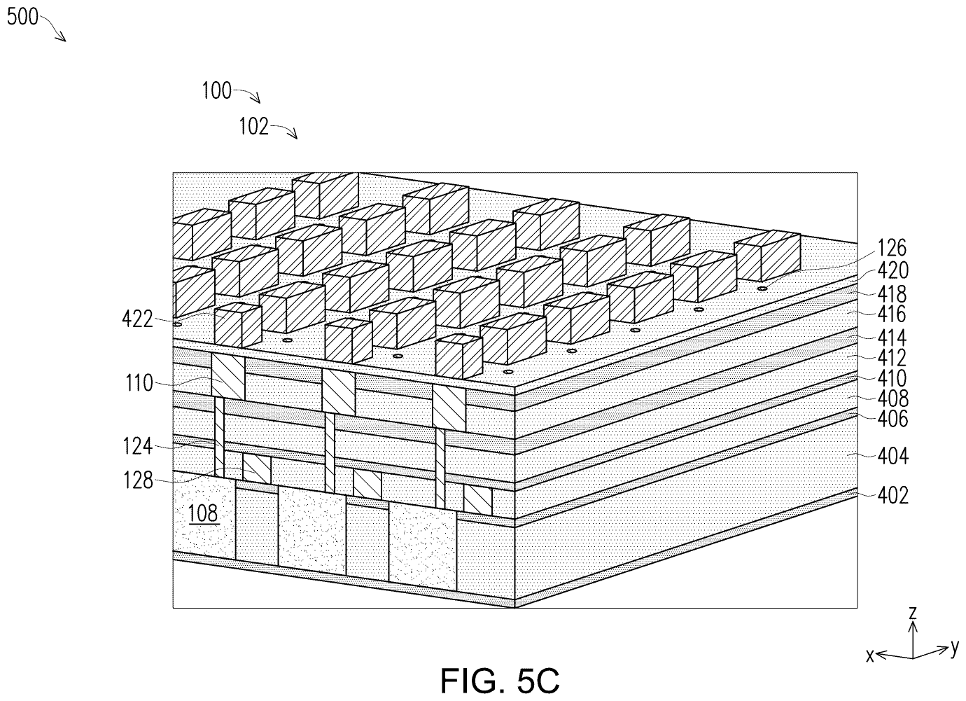

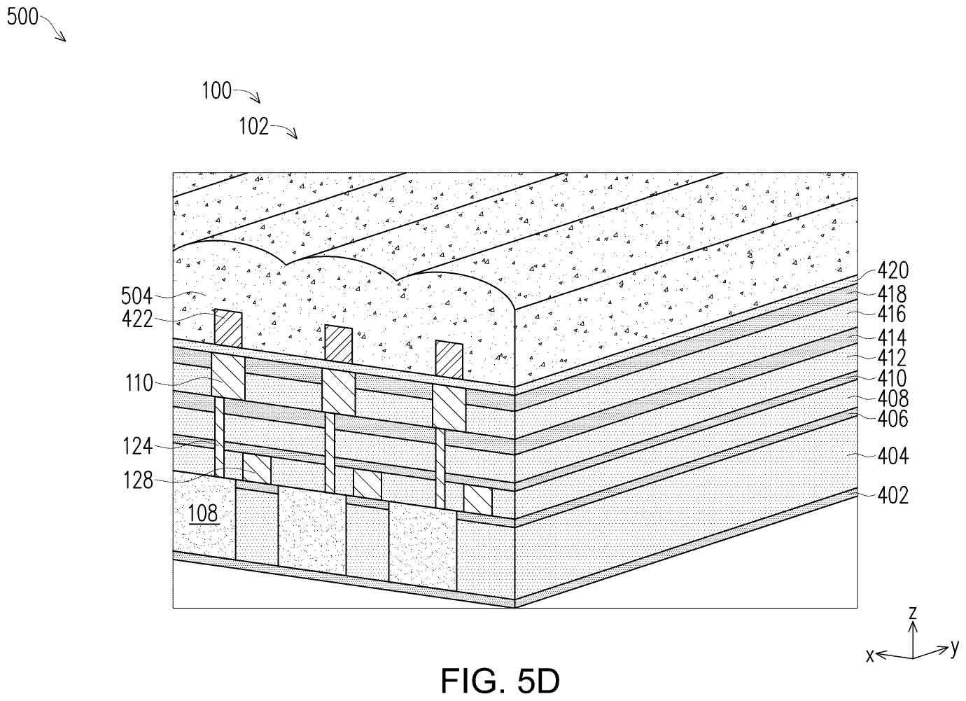

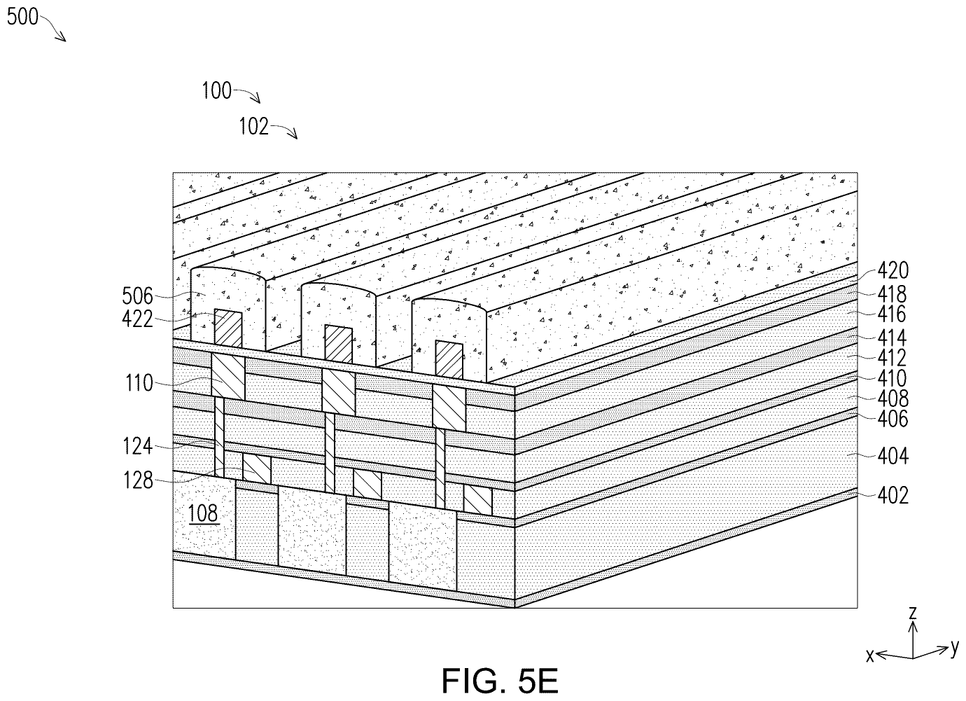

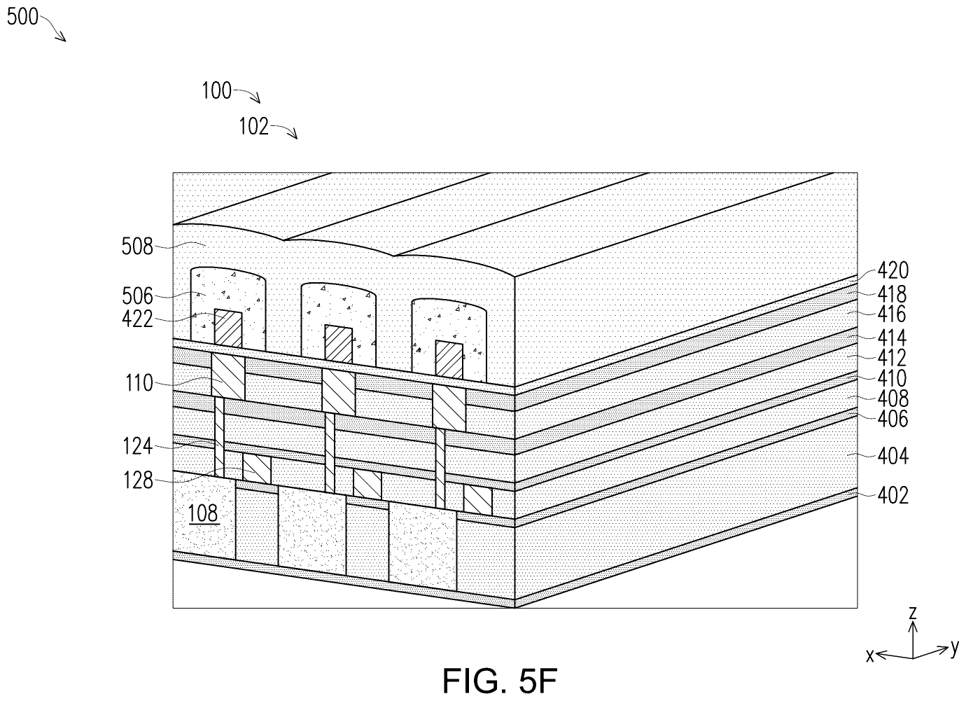

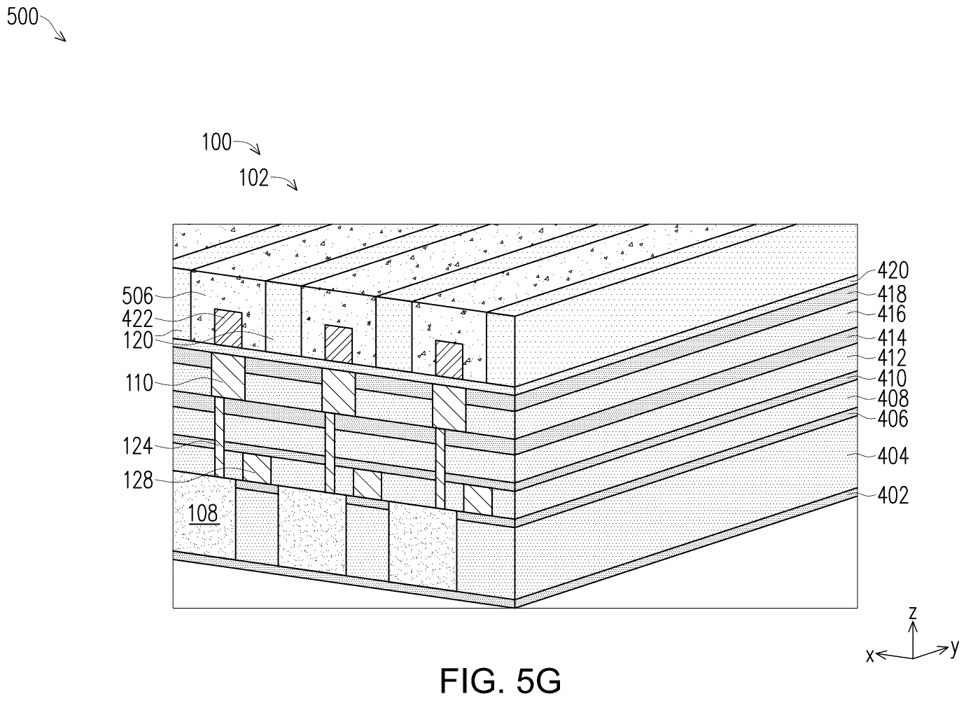

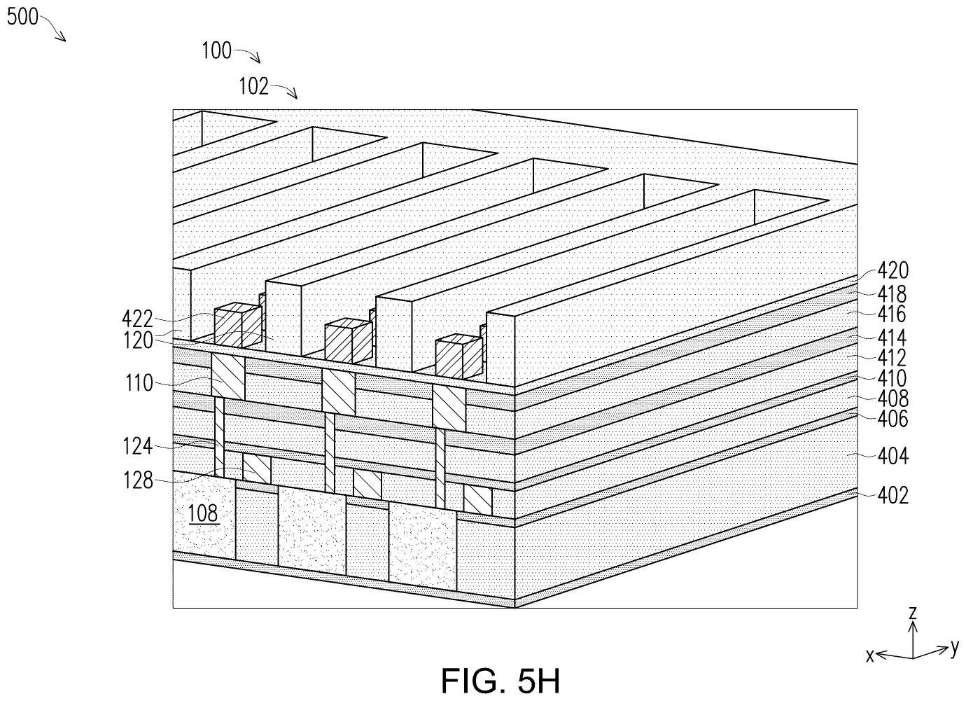

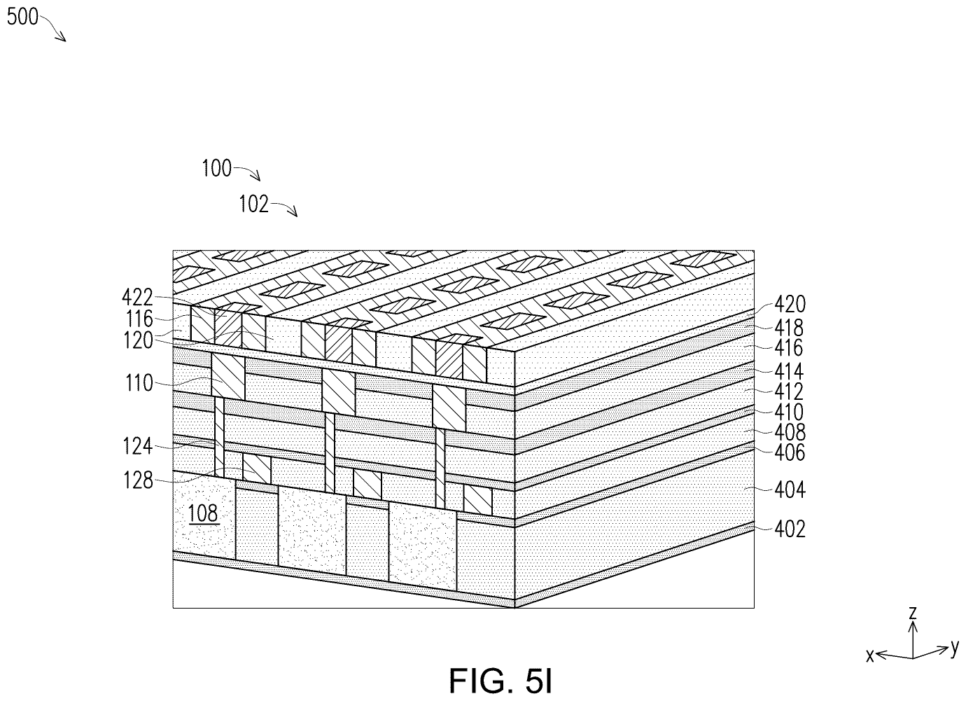

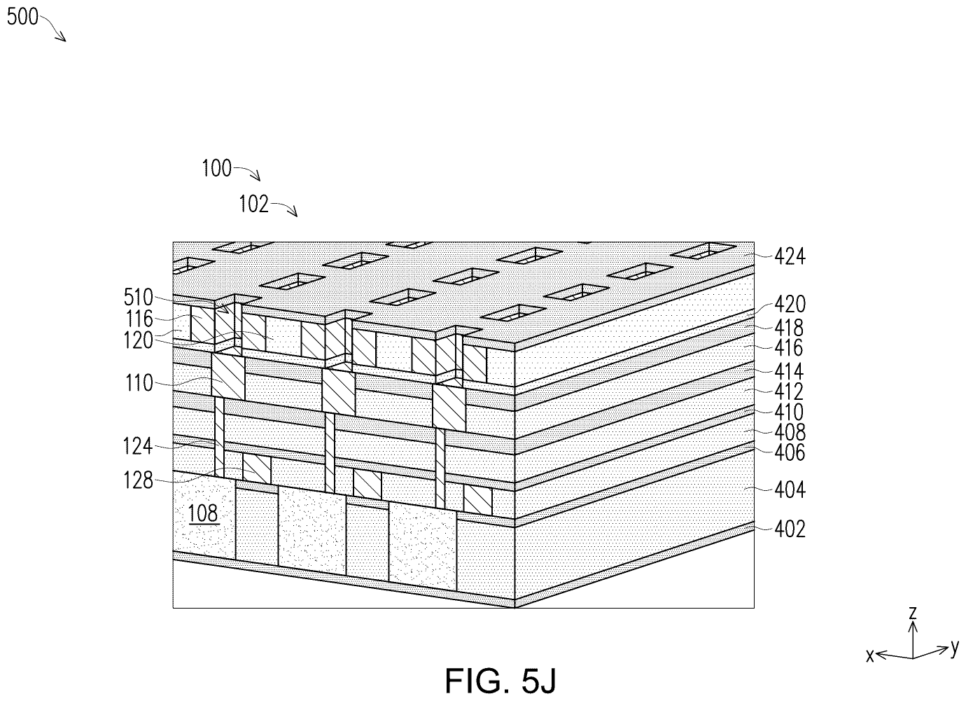

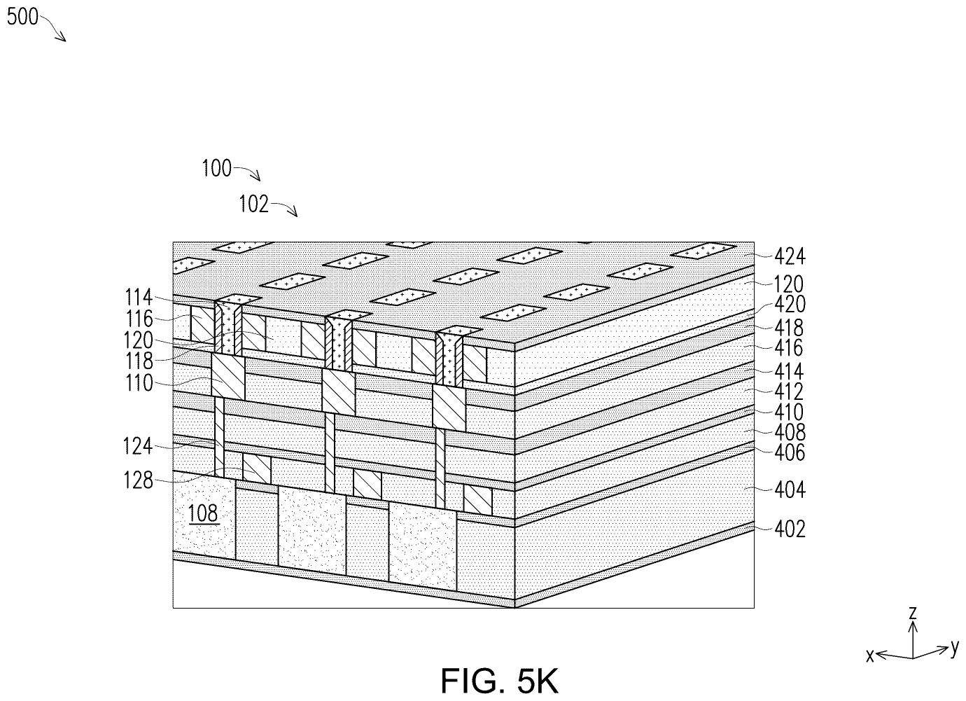

FIG. 4I illustrates another perspective view of the semiconductor device 100, and FIG. 4J illustrates a cross-section view along the line C-C (e.g., along the x-direction) in FIG. 4I. As shown in FIGS. 4I and 4J, the hydrogen-blocking columns 120 may be formed above the ILD layer 420. Channel spacers 422 may be formed above the ILD layer 420 as well. The gate electrodes 116 of the transistor structures 106 of the memory cell structures 104 may be formed around the channel spacers 422. The channel spacers 422 may be formed as temporary structures to preserve the space in which the channel layers 114 of the transistor structures 106 are to be formed. This enables the gate electrodes 116 to be formed around the channel spacers 422, enables the channel spacers 422 to be subsequently removed after formation of the gate electrodes 116, and enables the channel layers 114 to be formed in openings through the gate electrodes 116 that were previously occupied by the channel spacers 422. An example process for forming the hydrogen-blocking columns 120, the gate electrodes 116, and the channel spacers 422 is illustrated and described in connection with FIGS. 5A-5K.

The channel spacers 422 may include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material. A deposition tool may be used to deposit the channel spacers 422 using a PVD technique, an ALD technique, a CVD technique, an epitaxy technique, an oxidation technique, and/or another suitable deposition technique. The channel spacer may be formed above the source/drain electrodes 110 of the transistor structures 106.

In some implementations, the channel spacers 422 may be deposited as a blanket layer, patterned, and then etched to form the channel spacers 422. In some implementations, a planarization tool may be used to perform a planarization operation (e.g., a CMP operation) to planarize the channel spacers 422 after the channel spacers 422 are deposited.

A deposition tool may be used to deposit the hydrogen-blocking columns 120 using a PVD technique, an ALD technique, a CVD technique, an oxidation technique, and/or another suitable deposition technique. The hydrogen-blocking columns 120 may be deposited in one or more deposition operations. In some implementations, the hydrogen-blocking columns 120 may be deposited as a blanket layer, patterned, and then etched to form the hydrogen-blocking columns 120. In some implementations, a planarization tool may be used to perform a planarization operation (e.g., a CMP operation) to planarize the hydrogen-blocking columns 120 after the hydrogen-blocking columns 120 are deposited.

A deposition tool may be used to deposit the gate electrodes 116 using a CVD technique, a PVD technique, an ALD technique, an electroplating technique, and/or another suitable deposition technique. The hydrogen-blocking columns 120 and the channel spacers 422 may define the areas or regions in which the gate electrodes 116 are deposited. The gate electrodes 116 may be deposited in one or more deposition operations. In some implementations, a seed layer is first deposited, and the gate electrodes 116 are deposited on the seed layer. In some implementations, a planarization tool is used to perform a planarization operation (e.g., a CMP operation) to planarize the gate electrodes 116 after the gate electrodes 116 are deposited.

FIG. 4K illustrates another perspective view of the semiconductor device 100, and FIG. 4L illustrates a cross-section view along the line C-C (e.g., along the x-direction) in FIG. 4K. As shown in FIGS. 4K and 4L, another backend dielectric layer, such as an ESL 424, may be formed above the gate electrodes 116, the hydrogen-blocking columns 120, and/or the channel spacers 422. The ESL 424 may include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material. A deposition tool may be used to deposit the ESL 424 using a PVD technique, an ALD technique, a CVD technique, an oxidation technique, and/or another suitable deposition technique. The ESL 424 may be deposited in one or more deposition operations. In some implementations, a planarization tool may be used to perform a planarization operation (e.g., a CMP operation) to planarize the ESL 424 after the ESL 424 is deposited.

As further shown in FIGS. 4K and 4L, openings may be formed through the ESL 424 above the channel spacers 422, and the channel spacers 422 may be removed through the openings after formation of the gate electrodes 116 and after formation of the hydrogen-blocking columns 120. Removal of the channel spacers 422 results in formation of openings through the gate electrodes 116 above the source/drain electrodes 110. An etch tool may be used to etch the channel spacers 422 to remove the channel spacers 422 from the semiconductor device 100. In some implementations, the etch operation includes a dry etch operation (e.g., a plasma-based etch operation, a gas-based etch operation), a wet chemical etch operation, and/or another type of etch operation.

As further shown in FIGS. 4K and 4L, the channel layers 114 and the gate dielectric layers 118 may be formed in the openings through the gate electrodes 116 that were previously occupied by the channel spacers 422. In some implementations, the gate dielectric layers 118 may be formed on the sidewalls of the openings, and the channel layers 114 may fill in the openings. In some implementations, the gate dielectric layers 118 may be formed on the sidewalls of the openings, the outer section 302b of the channel layers 114 may be formed on the gate dielectric layers 118 on the sidewalls of the openings, and the core section 302a of the channel layers 302 may fill in the remaining arca in the openings.

A deposition tool may be used to deposit the gate dielectric layers 118 using a conformal deposition technique such as an ALD technique and/or a CVD technique, among other examples. A deposition tool may be used to deposit the channel layers 114 using a PVD technique, an ALD technique, a CVD technique, an oxidation technique, and/or another suitable deposition technique. The channel layers 114 may be deposited in one or more deposition operations. For example, the outer sections 302b may be deposited in a first deposition operation, and the core sections 302a may be deposited in a second deposition operation. In some implementations, a planarization tool may be used to perform a planarization operation (e.g., a CMP operation) to planarize the gate dielectric layers 118 and the channel layers 114 after the gate dielectric layers 118 and the channel layers 114 are deposited.

FIG. 4M illustrates another perspective view of the semiconductor device 100, and FIG. 4N illustrates a cross-section view along the line C-C (e.g., along the x-direction) in FIG. 4M. As shown in FIGS. 4M and 4N, additional dielectric layers (e.g., additional backend dielectric layers) may be formed in the semiconductor device 100. For example, another ILD layer 426 may be formed above and/or on the ESL 424. The ILD layer 426 may extend in the x-direction and in the y-direction. The ILD layer 426 may include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material.

A deposition tool may be used to deposit the ILD layer 426 using one or more deposition techniques, such as a PVD technique, an ALD technique, a CVD technique, an oxidation technique, and/or another suitable deposition technique. The ILD layer 426 may be deposited in one or more deposition operations. In some implementations, a planarization tool may be used to perform a planarization operation (e.g., a CMP operation) to planarize the ILD layer 426 after the ILD layer 426 is deposited.

As further shown in FIGS. 4M and 4N, the source/drain electrodes 112 of the transistor structures 106 of the memory cell structures 104 may be formed through the ILD layer 426 such that the source/drain electrodes 112 land on the channel layers 114 of the transistor structures 106. Forming the source/drain electrodes 112 may include forming recesses in and/or through the ILD layer 426, and forming the source/drain electrodes 112 in the recesses. In some implementations, a pattern in a photoresist layer is used to etch through the ILD layer 426 to form the recesses. In these implementations, a deposition tool may be used to form the photoresist layer on the ILD layer 426 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the ILD layer 426 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

In some implementations, one or more liners are first formed in the recesses, and the source/drain electrodes 112 are formed on the liner(s). The liner(s) may include adhesion liners (e.g., liners that are included to promote adhesion between the source/drain electrodes 112 and the surrounding layers such as the ILD layer 426), barrier layers (e.g., layers that are included to reduce or minimize diffusion of the material from the source/drain electrodes 112 into the surrounding layers such as the ILD layer 426), and/or another type of liner. Examples of materials for the liner(s) include tantalum nitride (TaN) and/or titanium nitride (TiN), among other examples. A deposition tool may be used to deposit the liner(s) in the recesses using an ALD technique, a CVD technique, and/or another type of conformal deposition technique.

A deposition tool may be used to deposit the source/drain electrodes 112 using a CVD technique, a PVD technique, an ALD technique, an electroplating technique, and/or another suitable deposition technique. In some implementations, a seed layer is first deposited on the liner(s), and the source/drain electrodes 112 are deposited on the seed layer. In some implementations, a planarization tool is used to perform a planarization operation (e.g., a CMP operation) to planarize the source/drain electrodes 112 after the source/drain electrodes 110 are formed. The top surfaces of the source/drain electrodes 112 may be approximately co-planar with the top surface of the ILD layer 426 after the planarization operation.

FIG. 4O illustrates another perspective view of the semiconductor device 100, and FIG. 4P illustrates a cross-section view along the line C-C (e.g., along the x-direction) in FIG. 4O. As shown in FIGS. 4O and 4P, additional dielectric layers (e.g., additional backend dielectric layers) may be formed in the semiconductor device 100. For example, another ILD layer 428 may be formed above and/or on the ILD layer 426. The ILD layer 426 may extend in the x-direction and in the y-direction. The ILD layer 426 may include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material.

A deposition tool may be used to deposit the ILD layer 428 using one or more deposition techniques, such as a PVD technique, an ALD technique, a CVD technique, an oxidation technique, and/or another suitable deposition technique. The ILD layer 428 may be deposited in one or more deposition operations. In some implementations, a planarization tool may be used to perform a planarization operation (e.g., a CMP operation) to planarize the ILD layer 428 after the ILD layer 428 is deposited.

As further shown in FIGS. 4O and 4P, the bit line conductive structures 122 of memory array 102 may be formed through the ILD layer 428 such that the bit line conductive structures 122 land on the source/drain electrodes 112 of the transistor structures 106 of the memory cell structures 104. The bit line conductive structures 122 may extend in the x-direction and may be arranged in the y-direction.

Forming the bit line conductive structures 122 may include forming recesses in and/or through the ILD layer 428, and forming the bit line conductive structures 122 in the recesses. In some implementations, a pattern in a photoresist layer is used to etch through the ILD layer 428 to form the recesses. In these implementations, a deposition tool may be used to form the photoresist layer on the ILD layer 428 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch through the ILD layer 428 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses based on a pattern.

In some implementations, one or more liners are first formed in the recesses, and the bit line conductive structures 122 are formed on the liner(s). The liner(s) may include adhesion liners (e.g., liners that are included to promote adhesion between the bit line conductive structures 122 and the surrounding layers such as the ILD layer 428), barrier layers (e.g., layers that are included to reduce or minimize diffusion of the material from the bit line conductive structures 122 into the surrounding layers such as the ILD layer 428), and/or another type of liner. Examples of materials for the liner(s) include tantalum nitride (TaN) and/or titanium nitride (TiN), among other examples. A deposition tool may be used to deposit the liner(s) in the recesses using an ALD technique, a CVD technique, and/or another type of conformal deposition technique.

A deposition tool may be used to deposit the bit line conductive structures 122 using a CVD technique, a PVD technique, an ALD technique, an electroplating technique, and/or another suitable deposition technique. In some implementations, a seed layer is first deposited on the liner(s), and the bit line conductive structures 122 are deposited on the seed layer. In some implementations, a planarization tool is used to perform a planarization operation (e.g., a CMP operation) to planarize the bit line conductive structures 122 after the bit line conductive structures 122 are formed. The top surfaces of the bit line conductive structures 122 may be approximately co-planar with the top surface of the ILD layer 428 after the planarization operation.

As indicated above, FIGS. 4A-4P are provided as an example. Other examples may differ from what is described with regard to FIGS. 4A-4P.

FIGS. 5A-5K are diagrams of an example implementation 500 of forming hydrogen-blocking columns 120 in a memory array 102 of a semiconductor device 100 described herein. In some implementations, one or more of the semiconductor processing operations described in connection with FIGS. 5A-5K may be performed using one or more semiconductor processing tools, such as a deposition tool, an exposure tool, a developer tool, an etch tool, a planarization tool, and/or an ion implantation tool, among other examples. In some implementations, one or more of the semiconductor processing operations described in connection with FIGS. 5A-5K may be performed as part of the process of forming the memory array 102 of the semiconductor device 100, as illustrated and described in connection with FIGS. 4A-4P.

As shown in a perspective view in FIG. 5A, one or more of the processing operations described in connection with FIGS. 4A-4F may be performed to form the backend dielectric layers 402-418 of the semiconductor device 100, the storage structures 108, the source/drain electrodes 110, the word line conductive structures 128, and the source/drain interconnect structures 124 of the of the memory cell structures 104.

As shown in a perspective view in FIG. 5B, the ILD layer 420 may be formed over and/or on the ESL 418, and a dielectric layer 502 may be formed over and/or on the ILD layer 420. The dielectric layer 502 may include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material. A deposition tool may be used to deposit the dielectric layer 502 using one or more deposition techniques, such as a PVD technique, an ALD technique, a CVD technique, an oxidation technique, and/or another suitable deposition technique. The dielectric layer 502 may be deposited in one or more deposition operations. In some implementations, a planarization tool may be used to perform a planarization operation (e.g., a CMP operation) to planarize the dielectric layer 502 after the dielectric layer 502 is deposited.

As shown in a perspective view FIG. 5C, the dielectric layer 502 is patterned and etched to define the channel spacers 422 from the dielectric layer 502. In some implementations, a pattern in a photoresist layer is used to etch the dielectric layer 502 to form the channel spacers 422. In these implementations, a deposition tool may be used to form the photoresist layer on the dielectric layer 502 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 502 based on the pattern to form the channel spacers 422. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 502 to form the channel spacers 422 based on a pattern.

As shown in a perspective view in FIG. 5D, another dielectric layer 504 may be formed over the ILD layer 420 and over the channel spacers 422 such that the channel spacers 422 are covered by the dielectric layer 504. The dielectric layer 504 may include one or more dielectric materials, such as an oxide, a nitride, a silicon oxide (SiOₓ), a silicon nitride (SiₓN_{y}), a silicon oxynitride (SiON), undoped silicate glass (USG), fluoride-doped silicate glass (FSG), a low-k dielectric material, a high-k dielectric material, and/or another suitable dielectric material. In some implementations, the material of the dielectric layer 502 may be different from the material of the channel spacers 422 to enable the dielectric layer 504 to be subsequently removed without removal of (or with minimal removal of) the channel spacers 422.

A deposition tool may be used to deposit the dielectric layer 504 using one or more deposition techniques, such as a PVD technique, an ALD technique, a CVD technique, an oxidation technique, and/or another suitable deposition technique. The dielectric layer 504 may be deposited in one or more deposition operations. In some implementations, a planarization tool may be used to perform a planarization operation (e.g., a CMP operation) to planarize the dielectric layer 504 after the dielectric layer 504 is deposited.

As shown in a perspective view in FIG. 5E, the dielectric layer 504 may be patterned and etched to define gate spacers 506. The gate spacers 506 may be included above the source/drain electrodes 110 and on the channel spacers 422. The gate spacers 506 may include temporary structures that occupy the regions in which the gate electrodes 116 are to be formed after formation of the hydrogen-blocking columns 120. In this way, the gate spacers 506 also define the spaces or areas in which the hydrogen-blocking columns 120 are to be formed.

In some implementations, a pattern in a photoresist layer is used to etch the dielectric layer 504 to form the gate spacers 506. In these implementations, a deposition tool may be used to form the photoresist layer on the dielectric layer 504 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 504 based on the pattern to define the gate spacers 506. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). For example, a plasma-based etch operation may be performed, in which a chamber pressure, a temperature, a plasma bias voltage, and/or another parameter is selected to control the directionality of the etch so that a vertical etch is achieved. In this way, the sidewalls of the trenches defined between adjacent gate spacers 506 are substantially vertical. In some implementations, a hard mask layer is used as an alternative technique for etching the dielectric layer 504 to form the gate spacers 506 based on a pattern.

As shown in a perspective view in FIG. 5F, a hydrogen-blocking layer 508 may be formed in the spaces (e.g., the trenches that extend in the y-direction) between the gate spacers 506. Thus, the hydrogen-blocking layer 508 may be formed along sidewalls and on the top surfaces of the gate spacers 506. A deposition tool may be used to deposit the hydrogen-blocking layer 508 using one or more deposition techniques, such as a PVD technique, an ALD technique, a CVD technique, an oxidation technique, and/or another suitable deposition technique. The hydrogen-blocking layer 508 may be deposited in one or more deposition operations.

As shown in a perspective view in FIG. 5G, the hydrogen-blocking layer 508 may be planarized to define the hydrogen-blocking columns 120 on opposing sides of the gate spacers 506. A planarization tool may be used to perform a planarization operation (e.g., a CMP operation) to planarize the hydrogen-blocking layer 508 to define the hydrogen-blocking columns 120. In some implementations, the planarization operation stops on the gate spacers 506. In some implementations, the planarization operation removes some material from the gate spacers 506 such that the top surfaces of the gate spacers 506 are substantially flat and co-planar with the tops of the hydrogen-blocking columns 120.

As shown in a perspective view in FIG. 5H, the gate spacers 506 are removed after planarizing the hydrogen-blocking layer 508 to define the hydrogen-blocking columns 120. Removal of the gate spacers 506 exposes the channel spacers 422 and the areas around the channel spacers 422 between the hydrogen-blocking columns 120. An etch tool may be used to etch the gate spacers 506 to remove the gate spacers 506 from the semiconductor device 100. In some implementations, the etch operation includes a dry etch operation (e.g., a plasma-based etch operation, a gas-based etch operation), a wet chemical etch operation, and/or another type of etch operation. An etchant that selectively etches the gate spacers 506 with minimal to no removal of material from the hydrogen-blocking columns 120 and material from the channel spacers 422 may be used to remove the gate spacers 506.

As shown in a perspective view in FIG. 5I, the gate electrodes 116 may be formed around the channel spacers 422 and between the hydrogen-blocking columns 120 in the areas that were previously occupied by the gate spacers 506. In some implementations, the gate electrodes 116 are deposited as a blanket layer, and the blanket layer and the hydrogen-blocking columns 120 are planarized (e.g., using a planarization tool) in a CMP operation and/or another type of planarization operation to define the gate electrodes 116. The CMP operation may stop on the channel spacers 422 such that the tops of the channel spacers 422 are exposed through the gate electrodes 116.

As shown in a perspective view in FIG. 5J, the channel spacers 422 are removed after formation of the gate electrodes 116, as described in connection with FIGS. 4K and 4L. Removal of the channel spacers 422 results in formation of openings 510 above the source/drain electrodes 110 of the transistor structures 106 of the memory cell structures 104. In addition, the ILD layer 420 directly under the channel spacers 422 are also removed, so that the source/drain electrodes 110 are exposed by the openings 510, as shown in FIG. 5J in accordance with some embodiments.

As shown in a perspective view in FIG. 5K, the gate dielectric layers 118 and the channel layers 114 may be formed in the openings 510 above the source/drain electrodes 110, as described in connection with FIGS. 4K and 4L.

As indicated above, FIGS. 5A-5K are provided as an example. Other examples may differ from what is described with regard to FIGS. 5A-5K.

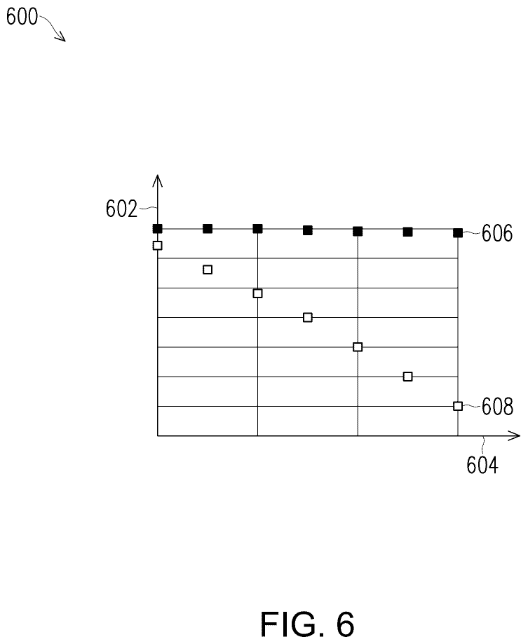

FIG. 6 is a diagram of an example 600 of temperature bias instability for various memory cell structures. The temperature bias instability (e.g., PTBI, NTBI) is illustrated as a function of threshold voltage shift 602 and stress time 604. Data plots 606 correspond to threshold voltage shift 602 over stress time 604 for a memory cell structure 104 described herein that includes hydrogen-blocking columns 120, and data plots 608 correspond to threshold voltage shift 602 over stress time 604 for a memory cell structure that does not include hydrogen-blocking columns 120.

As shown by the data plots 608 in FIG. 6, without the hydrogen-blocking columns 120, the memory cell structure experiences a significant (negative) threshold voltage shift 602 as stress time 604 on the memory cell structure increases. This occurs because of the increase in carrier dosage in the channel layer of the memory cell structure as a result of exposure to hydrogen in the absence of hydrogen-blocking columns 120.

As shown by the data plots 606 in FIG. 6, without the hydrogen-blocking columns 120, the memory cell structure 104 described herein experiences minimal to no threshold voltage shift 602 as stress time 604 on the memory cell structure 104 increases. This is because the hydrogen-blocking columns 120 prevent, minimize, and/or otherwise reduce the exposure of the channel layer 114 to hydrogen, which enables a relatively consistent and uniform carrier dosage to be maintained in the channel layer 114 over stress time 604 for the memory cell structure 104.

As indicated above, FIG. 6 is provided as an example. Other examples may differ from what is described with regard to FIG. 6.

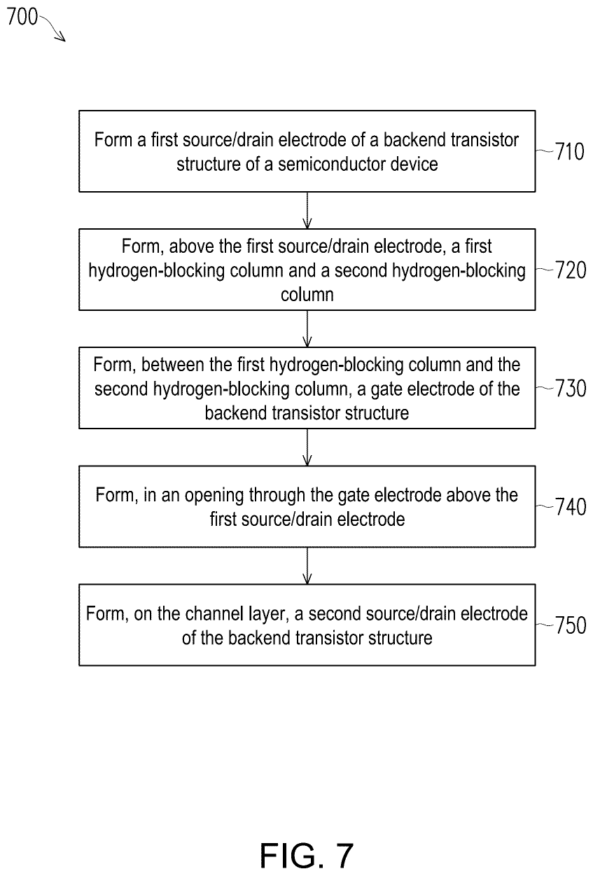

FIG. 7 is a flowchart of an example process 700 associated with forming a memory cell structure described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include forming a first source/drain electrode of a backend transistor structure of a semiconductor device (block 710). For example, one or more semiconductor processing tools may be used to form a first source/drain electrode (e.g., a source/drain electrode 110) of a backend transistor structure (e.g., a transistor structure 106) of a semiconductor device (e.g., a semiconductor device 100), as described herein.

As further shown in FIG. 7, process 700 may include forming, above the first source/drain electrode, a first hydrogen-blocking column and a second hydrogen-blocking column (block 720). For example, one or more semiconductor processing tools may be used to form, above the first source/drain electrode, a first hydrogen-blocking column (e.g., a hydrogen-blocking column 120) and a second hydrogen-blocking column (e.g., a hydrogen-blocking column 120), as described herein.

As further shown in FIG. 7, process 700 may include forming, between the first hydrogen-blocking column and the second hydrogen-blocking column, a gate electrode of the backend transistor structure (block 730). For example, one or more semiconductor processing tools may be used to form, between the first hydrogen-blocking column and the second hydrogen-blocking column, a gate electrode (e.g., a gate electrode 116) of the backend transistor structure, as described herein.

As further shown in FIG. 7, process 700 may include forming, in an opening through the gate electrode above the first source/drain electrode, a gate dielectric layer, of the backend transistor structure, on sidewalls of the opening, and a channel layer, of the backend transistor structure, on the first source/drain electrode (block 740). For example, one or more semiconductor processing tools may be used to form, in an opening (e.g., an opening 510) through the gate electrode above the first source/drain electrode, a gate dielectric layer (e.g., a gate dielectric layer 118), of the backend transistor structure, on sidewalls of the opening, and a channel layer (e.g., a channel layer 114), of the backend transistor structure, on the first source/drain electrode, as described herein.

As further shown in FIG. 7, process 700 may include forming, on the channel layer, a second source/drain electrode of the backend transistor structure (block 750). For example, one or more semiconductor processing tools may be used to form, on the channel layer, a second source/drain electrode of the backend transistor structure, as described herein.

Process 700 may include additional implementations, such as any single implementation or any combination of implementations described below and/or in connection with one or more other processes described elsewhere herein.

In a first implementation, forming the gate electrode includes forming a channel spacer (e.g., a channel spacer 422) above the first source/drain electrode, and forming the gate electrode around the channel spacer.

In a second implementation, alone or in combination with the first implementation, forming the channel layer includes removing the channel spacer after forming the gate electrode, removal of the channel spacer results in formation of the opening through the gate electrode, and forming the channel layer in the opening previously occupied by the channel spacer.

In a third implementation, alone or in combination with one or more of the first and second implementations, forming the first hydrogen-blocking column and the second hydrogen-blocking column includes forming a gate spacer (e.g., a gate spacer 506) above the first source/drain electrode, forming a hydrogen-blocking layer (e.g., a hydrogen-blocking layer 508) along sidewalls and on a top surface of the gate spacer, and planarizing the hydrogen-blocking layer to form the first hydrogen-blocking column and the second hydrogen-blocking column from the hydrogen-blocking layer.

In a fourth implementation, alone or in combination with one or more of the first through third implementations, forming the gate electrode includes removing the gate spacer after planarizing the hydrogen-blocking layer, and depositing the gate electrode in areas between the first hydrogen-blocking column and the second hydrogen-blocking column previously occupied by the gate spacer.

In a fifth implementation, alone or in combination with one or more of the first through fourth implementations, forming the channel layer includes forming an outer section (e.g., an outer section 302b) of the channel layer on the gate dielectric layer, and filling in the opening through the gate electrode with a core section (e.g., a core section 302a) of the channel layer, where the outer section of the channel layer is between the core section of the channel layer and the gate dielectric layer.

In a sixth implementation, alone or in combination with one or more of the first through fifth implementations, forming the outer section of the channel layer includes forming the outer section to include a first oxide-semiconductor material having a first dopant concentration, and forming the core section of the channel layer includes forming the core section to include a second oxide-semiconductor material having a second dopant concentration that is less than the first dopant concentration.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, hydrogen-blocking columns may be included between a gate electrode of a transistor structure and one or more other layers of a semiconductor device to prevent, minimize, and/or otherwise reduce hydrogen diffusion into a channel layer of the transistor structure. The hydrogen-blocking columns include one or more materials that resist absorption of hydrogen, which prevents, minimizes, and/or otherwise reduces the likelihood of the hydrogen diffusing into the vertical channel layer of the transistor structure. In this way, the hydrogen-blocking columns prevent, minimize, and/or otherwise reduce the likelihood of hydrogen contamination in the channel layer, which may enable a low current leakage to be achieved for the transistor structure.

As described in greater detail above, some implementations described herein provide a semiconductor device. The semiconductor device includes a plurality of backend dielectric layers. The semiconductor device includes a transistor structure in the plurality of backend dielectric layers. The transistor structure includes a first source/drain electrode, a second source/drain electrode above the first source/drain electrode, a channel layer that vertically extends between the first source/drain electrode and the second source/drain electrode, a gate electrode laterally wrapping around the channel layer, and one or more hydrogen-blocking columns extending along one or more sides of the gate electrode.

As described in greater detail above, some implementations described herein provide a method. The method includes forming a first source/drain electrode of a backend transistor structure of a semiconductor device. The method includes forming, above the first source/drain electrode, a first hydrogen-blocking column and a second hydrogen-blocking column. The method includes forming, between the first hydrogen-blocking column and the second hydrogen-blocking column, a gate electrode of the backend transistor structure. The method includes forming, in an opening through the gate electrode above the first source/drain electrode: a gate dielectric layer, of the backend transistor structure, on sidewalls of the opening, and a channel layer, of the backend transistor structure, on the first source/drain electrode. The method includes forming, on the channel layer, a second source/drain electrode of the backend transistor structure.

As described in greater detail above, some implementations described herein provide a semiconductor device. The semiconductor device includes a plurality of backend dielectric layers. The semiconductor device includes a memory cell structure in the plurality of backend dielectric layers. The memory cell structure includes a storage structure (108) and a transistor structure above the storage structure. The transistor structure includes a first source/drain electrode, a second source/drain electrode, above the first source/drain electrode, a channel layer that vertically extends between the first source/drain electrode and the second source/drain electrode, a gate electrode laterally wrapping around the channel layer, a first hydrogen-blocking column extending along a first side of the gate electrode, and a second hydrogen-blocking column extending along a second side of the gate electrode opposite the first side.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of backend dielectric layers; and
a transistor structure, in the plurality of backend dielectric layers, comprising:
a first source/drain electrode;
a second source/drain electrode above the first source/drain electrode;
a channel layer that vertically extends between the first source/drain electrode and the second source/drain electrode;
a gate electrode laterally wrapping around the channel layer; and
one or more hydrogen-blocking columns extending along one or more sides of the gate electrode.

2. The semiconductor device of claim 1, wherein the one or more hydrogen-blocking columns include at least one of:
a nitride-containing dielectric material, or
an oxide-containing dielectric material.

3. The semiconductor device of claim 1, wherein bottom surfaces of the one or more hydrogen-blocking columns are approximately co-planar with a bottom surface of the gate electrode; and
wherein top surfaces of the one or more hydrogen-blocking columns are approximately co-planar with a top surface of the gate electrode.

4. The semiconductor device of claim 1, wherein the channel layer comprises at least one of:
a p-type oxide-semiconductor material, or
an n-type oxide-semiconductor material.

5. The semiconductor device of claim 1, wherein the channel layer comprises:
a core section including a first semiconductor material having a first dopant concentration; and
an outer section wrapped around the core section,
wherein the outer section includes a second semiconductor material having a second dopant concentration that is different from the first dopant concentration.

6. The semiconductor device of claim 5, wherein the second dopant concentration is greater than the first dopant concentration.

7. The semiconductor device of claim 1, wherein the one or more hydrogen-blocking columns continuously extend alongside a plurality of gate electrodes of a plurality of transistor structures in the semiconductor device.

8. A method, comprising:
forming a first source/drain electrode of a backend transistor structure of a semiconductor device;
forming, above the first source/drain electrode, a first hydrogen-blocking column and a second hydrogen-blocking column;
forming, between the first hydrogen-blocking column and the second hydrogen-blocking column, a gate electrode of the backend transistor structure;
forming, in an opening through the gate electrode above the first source/drain electrode:
a gate dielectric layer, of the backend transistor structure, on sidewalls of the opening, and
a channel layer, of the backend transistor structure, on the first source/drain electrode; and
forming, on the channel layer, a second source/drain electrode of the backend transistor structure.

9. The method of claim 8, wherein forming the gate electrode comprises:
forming a channel spacer above the first source/drain electrode; and
forming the gate electrode around the channel spacer.

10. The method of claim 9, wherein forming the channel layer comprises:
removing the channel spacer after forming the gate electrode,
wherein removal of the channel spacer results in formation of the opening through the gate electrode;
and forming the channel layer in the opening previously occupied by the channel spacer.

11. The method of claim 8, wherein forming the first hydrogen-blocking column and the second hydrogen-blocking column comprises:
forming a gate spacer above the first source/drain electrode;
forming a hydrogen-blocking layer along sidewalls and on a top surface of the gate spacer; and
planarizing the hydrogen-blocking layer to form the first hydrogen-blocking column and the second hydrogen-blocking column from the hydrogen-blocking layer.

12. The method of claim 11, wherein forming the gate electrode comprises:
removing the gate spacer after planarizing the hydrogen-blocking layer; and
depositing the gate electrode in areas between the first hydrogen-blocking column and the second hydrogen-blocking column previously occupied by the gate spacer.

13. The method of claim 8, wherein forming the channel layer comprises:
forming an outer section of the channel layer on the gate dielectric layer; and
filling in the opening through the gate electrode with a core section of the channel layer,
wherein the outer section of the channel layer is between the core section of the channel layer and the gate dielectric layer.

14. The method of claim 13, wherein forming the outer section of the channel layer comprises:
forming the outer section to include a first oxide-semiconductor material having a first dopant concentration; and
wherein forming the core section of the channel layer comprises:
forming the core section to include a second oxide-semiconductor material having a second dopant concentration that is less than the first dopant concentration.

15. A semiconductor device, comprising:
a plurality of backend dielectric layers; and
a memory cell structure, in the plurality of backend dielectric layers, comprising:
a storage structure; and
a transistor structure, above the storage structure, comprising:
a first source/drain electrode;
a second source/drain electrode above the first source/drain electrode;
a channel layer that vertically extends between the first source/drain electrode and the second source/drain electrode;
a gate electrode laterally wrapping around the channel layer;
a first hydrogen-blocking column extending along a first side of the gate electrode; and
a second hydrogen-blocking column extending along a second side of the gate electrode opposite the first side.

16. The semiconductor device of claim 15, wherein the first hydrogen-blocking column and the second hydrogen-blocking column each include at least one of:
aluminum nitride (AlN),
aluminum oxynitride (AlON), or
aluminum oxide (AlₓO_{y}).

17. The semiconductor device of claim 15, wherein a lateral width across the first hydrogen-blocking column is included in a range of approximately 10 nanometers to approximately 100 nanometers.

18. The semiconductor device of claim 15, wherein the second source/drain electrode is coupled to a bit line conductive structure above the second source/drain electrode;
wherein the bit line conductive structure extends in a first lateral direction (x-direction) in the semiconductor device; and
wherein the first hydrogen-blocking column and the second hydrogen-blocking column each extend in a second lateral direction, in the semiconductor device, that is approximately perpendicular to the first lateral direction.

19. The semiconductor device of claim 15, wherein the gate electrode is coupled to a word line interconnect structure below the gate electrode;
wherein the word line interconnect structure is coupled to a word line conductive structure below the word line via structure; and
wherein the word line conductive structure, the first hydrogen-blocking column, and the second hydrogen-blocking column each extend in a lateral direction in the semiconductor device.

20. The semiconductor device of claim 15, wherein the first hydrogen-blocking column and the second hydrogen-blocking column each include at least one of:
silicon nitride (SiₓN_{y}),
silicon carbon nitride (SiCN), or
silicon carbon oxynitride (SiCON).
